(19) United States
(12) Patent Application Publication
(10) Pub. No.: US 2026/0311780 A1
(43) Pub. Date: Oct. 8, 2026

(54) SEMICONDUCTOR DEVICE AND OPERATION METHOD THEREOF, SYSTEM, AND ELECTRONIC DEVICE

(71) Applicant: CCSH Corporation, Wuhan (CN)

(72) Inventors: Zongliang HUO, Wuhan (CN); Yu Zhang, Wuhan (CN); Lei Jin, Wuhan (CN); Feng Xu, Wuhan (CN); Yuanyuan Min, Wuhan (CN); Xinran Li, Wuhan (CN); Wendong Wang, Wuhan (CN)

(73) Assignee: CCSH Corporation, Wuhan (CN)

(21) Appl. No.: 19/406,664

(22) Filed: Dec. 2, 2025

Related U.S. Application Data
(63) Continuation of application No. PCT/CN2025/087332, filed on Apr. 3, 2025.

(51) Int. Cl. G11C 16/34; G11C 16/10; G11C 16/26; G11C 16/30

(52) U.S. Cl. CPC G11C 16/3459; G11C 16/102; G11C 16/26; G11C 16/30

(57) ABSTRACT

A semiconductor device is provided. The semiconductor device includes a memory array with memory cells and includes a peripheral circuit; the peripheral circuit is configured to: in a first phase, perform a first program operation on a first memory cell coupled to a first word line in a first word line group; in a second phase, perform a second program operation on a second memory cell coupled to a second word line in a second word line group to write weight data into the second memory cell; in a third phase, perform a third program operation on a third memory cell coupled to a third word line in the first word line group; and in the third phase, apply a first read voltage to a fourth word line in a third word line group to obtain a current of a bit line coupled to the third memory cell.

### CROSS-REFERENCE TO RELATED APPLICATIONS

This application is a continuation of International Application No. PCT/CN2025/087332, filed on Apr. 3, 2025, which is hereby incorporated by reference in its entirety.

### TECHNICAL FIELD

The present disclosure relates to the field of semiconductor technology, and more particularly to, but not limited to, a semiconductor device and an operation method thereof, a system, and an electronic device.

### BACKGROUND

In a classical Von Neumann computing architecture, a memory is separated from a processor, and data is transmitted between the memory and the processor through a data bus. When executing a command, the processor first reads the data from the memory, and then writes the updated data back into the memory after processing is completed, the frequent data migration brings huge power consumption and time overheads. In addition, since the memory bandwidth is limited, the processing speed of the processor is limited by the access speed of the memory, which greatly affects computing performance. With the rise of applications such as big data and artificial intelligence, massive data processing makes the bottleneck of the Von Neumann computing architecture more and more prominent.

### SUMMARY

According to a first aspect of implementations of the present disclosure, there is provided a semiconductor device including a memory array and a peripheral circuit coupled to the memory array; the memory array includes a plurality of memory cells, and the peripheral circuit is configured to: in a first phase, perform a first program operation on a first memory cell coupled to a first word line in a first word line group; in a second phase, perform a second program operation on a second memory cell coupled to a second word line in a second word line group to write weight data into the second memory cell; and in a third phase, perform a third program operation on a third memory cell coupled to a third word line in the first word line group; and in the third phase, apply a first read voltage to a fourth word line in a third word line group to obtain a current of a bit line coupled to the third memory cell.

In some implementations, the memory cells in the memory array are configured to have an erase state; the memory cells in the erase state correspond to a first voltage-current relationship; a first current is a current in a saturation region in the first voltage-current relationship; and the first read voltage is a voltage corresponding to the first current in the first voltage-current relationship.

In some implementations, the memory cells in the memory array are configured to have a program state, and the memory cells in the program state correspond to a second voltage-current relationship; and the first read voltage is less than a voltage in a linear region in the second voltage-current relationship.

In some implementations, the peripheral circuit is configured to: apply a first validation voltage to the first word line in a validation phase of the first program operation; apply a second validation voltage to the second word line in a validation phase of the second program operation; apply a third validation voltage to the third word line in a validation phase of the third program operation; a threshold voltage of the first memory cell is a first threshold voltage after the first program operation is performed on the first memory cell, and a threshold voltage of the third memory cell is a second threshold voltage after the third program operation is performed on the third memory cell; the first validation voltage is different from the third validation voltage; or the first threshold voltage is different from the second threshold voltage.

In some implementations, the first threshold voltage is different from the second threshold voltage, and the first validation voltage is equal to the third validation voltage.

In some implementations, the first validation voltage is different from the third validation voltage, and the first threshold voltage is equal to the second threshold voltage.

In some implementations, the first validation voltage is greater than the third validation voltage.

In some implementations, memory cells in the memory array are configured to have an erase state; the memory cells in the erase state correspond to the first voltage-current relationship, and the memory cells in the program state correspond to the second voltage-current relationship; a second current is a current in a linear region in the second voltage-current relationship, and a third current is current in a transition region in the second voltage-current relationship; the first validation voltage is a voltage corresponding to the second current in the second voltage-current relationship; and the third validation voltage is a voltage corresponding to the third current in the second voltage-current relationship.

In some implementations, the first memory cell, the second memory cell, and the third memory cell belong to the same memory string.

In some implementations, the peripheral circuit is configured to: apply a corresponding program voltage to the first word line and apply a ground voltage to a bit line coupled to the first memory cell in a program phase of the first program operation; apply a corresponding program voltage to the second word line and apply the ground voltage to a bit line coupled to the second memory cell in a program phase of the second program operation; and apply a corresponding program voltage to the third word line and apply the ground voltage to a bit line coupled to the third memory cell in a program phase of the third program operation.

In some implementations, in the third phase, the peripheral circuit is configured to pre-charge a sensing node coupled to the bit line coupled to the third memory cell to a target voltage.

In some implementations, in the third phase, the peripheral circuit is configured to: finish the third phase in response to a current of the bit line coupled to the third memory cell being within a preset range.

In some implementations, the peripheral circuit is configured to: perform the third program operation on a memory cell belonging to a memory string to which the third memory cell belongs among memory cells coupled to a fifth word line in response to the third memory cell passing a validation and the current of the bit line coupled to the third memory cell exceeding the preset range; or continue to perform the third program operation on the third memory cell in response to the third memory cell failing the validation and the current of the bit line coupled to the third memory cell exceeding the preset range.

In some implementations, the preset range includes 30 nA to 50 nA.

In some implementations, the peripheral circuit is configured to: apply corresponding turn-on voltages to a top select line and a bottom select line coupled to the third memory cell, and word lines other than the fourth word line, respectively, during a same period of applying the first read voltage to the fourth word line.

In some implementations, each of memory cells coupled to the fourth word line is in the erase state at least in the third phase.

In some implementations, in the third phase, the peripheral circuit is configured to: pre-charge sensing nodes coupled to bit lines individually coupled to a plurality of third memory cells to a target voltage; the plurality of the third memory cells are coupled to the same top select line, and the plurality of third memory cells are individually coupled to different bit lines; and obtain currents of the bit lines individually coupled to the plurality of third memory cells.

In some implementations, the second phase follows the first phase, and the third phase follows the second phase.

In some implementations, the peripheral circuit is configured to perform an erase operation on each of the memory cells of the memory array before the first phase, the second phase, and the third phase.

In some implementations, in an operation phase, the peripheral circuit is configured to: after the third phase, apply a second read voltage to the second word line, apply a corresponding input voltage to a top select line or a bottom select line coupled to the second memory cell, and apply corresponding turn-on voltages to word lines other than the second word line respectively; pre-charge a sensing node coupled to a bit line coupled to the second memory cell to a target voltage; and obtain a current of the bit line coupled to the second memory cell.

In some implementations, the semiconductor device includes a three-dimensional NAND type memory.

According to a second aspect of the present disclosure, there is provided a system, including: at least one semiconductor device, where the semiconductor device is the semiconductor device according to any one of the above implementations; and a controller coupled to the at least one semiconductor device and configured to send input data to the semiconductor device and receive an operation result of the semiconductor device.

In some implementations, the system further includes an analog-to-digital conversion circuit and a data processing circuit; the analog-to-digital conversion circuit is configured to convert analog calculation information into digital calculation information; and the data processing circuit is configured to perform a first operation on the digital calculation information to obtain the operation result.

According to a third aspect of implementations of the present disclosure, there is provided an electronic device including the system according to any one of the above implementations and a host coupled to the system.

According to a fourth aspect of implementations of the present disclosure, there is provided an operation method of a semiconductor device, including: in a first phase, performing a first program operation on a first memory cell coupled to a first word line in a first word line group; in a second phase, performing a second program operation on a second memory cell coupled to a second word line in a second word line group to write weight data into the second memory cell; and in a third phase, performing a third program operation on a third memory cell coupled to a third word line in the first word line group; and in the third phase, applying a first read voltage to a fourth word line in a third word line group to obtain a current of a bit line coupled to the third memory cell.

In some implementations, memory cells in a memory array are configured to have an erase state; the memory cells in the erase state correspond to a first voltage-current relationship; a first current is a current in a saturation region in the first voltage-current relationship; and the first read voltage is a voltage corresponding to the first current in the first voltage-current relationship.

In some implementations, the memory cells in the memory array are configured to have a program state, and the memory cells in the program state correspond to a second voltage-current relationship; and the first read voltage is less than a voltage in a linear region in the second voltage-current relationship.

In some implementations, the performing the first program operation on the first memory cell coupled to the first word line includes: applying a first validation voltage to the first word line in a validation phase of the first program operation; the performing the second program operation on the second memory cell coupled to the second word line includes: applying a second validation voltage to the second word line in a validation phase of the second program operation; the performing the third program operation on the third memory cell coupled to the third word line includes: applying a third validation voltage to the third word line in a validation phase of the third program operation; a threshold voltage of the first memory cell is a first threshold voltage after the first program operation is performed on the first memory cell, and a threshold voltage of the third memory cell is a second threshold voltage after the third program operation is performed on the third memory cell; the first validation voltage is different from the third validation voltage; or the first threshold voltage is different from the second threshold voltage.

In some implementations, the first threshold voltage is different from the second threshold voltage, and the first validation voltage is equal to the third validation voltage.

In some implementations, the first validation voltage is different from the third validation voltage, and the first threshold voltage is equal to the second threshold voltage.

In some implementations, the first validation voltage is greater than the third validation voltage.

In some implementations, memory cells in the memory array are configured to have an erase state; the memory cells in the erase state correspond to a first voltage-current relationship, and memory cells in the program state correspond to a second voltage-current relationship; where a second current is a current in a linear region in the second voltage-current relationship, and a third current is a current in a transition region in the second voltage-current relationship; the first validation voltage is a voltage corresponding to the second current in the second voltage-current relationship; and the third validation voltage is a voltage corresponding to the third current in the second voltage-current relationship.

In some implementations, the first memory cell, the second memory cell, and the third memory cell belong to the same memory string.

In some implementations, the performing the first program operation on the first memory cell coupled to the first word line includes: applying a corresponding program voltage to the first word line and applying a ground voltage to a bit line coupled to the first memory cell in a program phase of the first program operation; the performing the second program operation on the second memory cell coupled to the second word line includes: applying a corresponding program voltage to the second word line and applying the ground voltage to a bit line coupled to the second memory cell in a program phase of the second program operation; and the performing the third program operation on the third memory cell coupled to the third word line includes: applying a corresponding program voltage to the third word line and applying the ground voltage to a bit line coupled to the third memory cell in a program phase of the third program operation.

In some implementations, in the third phase, the operation method further includes: pre-charging a sensing node coupled to the bit line coupled to the third memory cell to a target voltage.

In some implementations, in the third phase, the operation method further includes: finishing the third phase in response to a current of the bit line coupled to the third memory cell being within a preset range.

In some implementations, the operation method further includes: performing the third program operation on a memory cell belonging to a memory string to which the third memory cell belongs among memory cells coupled to a fifth word line in response to the third memory cell passing a validation and the current of the bit line coupled to the third memory cell exceeding the preset range; or continuing to perform the third program operation on the third memory cell in response to the third memory cell failing the validation and the current of the bit line coupled to the third memory cell exceeding the preset range.

In some implementations, each of memory cells coupled to the fourth word line is in the erase state at least in the third phase.

In some implementations, in the third phase, the operation method further includes: pre-charging sensing nodes coupled to bit lines individually coupled to a plurality of third memory cells to a target voltage; the plurality of third memory cells are coupled to the same top select line, and the plurality of third memory cells are individually coupled to different bit lines; and the obtaining the current of the bit line coupled to the third memory cell includes: obtaining currents of the bit lines individually coupled to the plurality of third memory cells.

In some implementations, the second phase follows the first phase, and the third phase follows the second phase.

In some implementations, the method further includes: performing an erase operation on each of the memory cells of the memory array before the first phase, the second phase, and the third phase.

In some implementations, in an operation phase, the operation method further includes: after the third phase, applying a second read voltage to the second word line, applying a corresponding input voltage to a top select line or a bottom select line coupled to the second memory cell, and applying corresponding turn-on voltages to word lines other than the second word line respectively; pre-charging a sensing node coupled to the bit line coupled to the second memory cell to a target voltage; and obtaining a current of the bit line coupled to the second memory cell.

### BRIEF DESCRIPTION OF DRAWINGS

FIG. 1 is a first schematic structural diagram of a semiconductor device provided by an implementation of the present disclosure;

FIG. 2 is a second schematic structural diagram of a semiconductor device provided by an implementation of the present disclosure;

FIG. 3 is a schematic distribution diagram of memory cells of a semiconductor device provided by an implementation of the present disclosure;

FIG. 4 is a schematic diagram of an exemplary semiconductor device including a peripheral circuit provided by an implementation of the present disclosure;

FIG. 5 is a schematic cross-sectional view of a memory array including memory strings provided by an implementation of the present disclosure;

FIG. 6 is a schematic diagram of a semiconductor device provided by an implementation of the present disclosure;

FIG. 7 is a schematic diagram of inputting an input voltage from a top select line into a block provided by an implementation of the present disclosure;

FIG. 8 is a first schematic diagram of a plurality of memory strings coupled to one bit line provided by an implementation of the present disclosure;

FIG. 9 is a second schematic diagram of a plurality of memory strings coupled to one bit line provided by an implementation of the present disclosure;

FIG. 10 is a schematic diagram of voltage curves in a program phase and a validation phase of a first phase provided by an implementation of the present disclosure;

FIG. 11 is a schematic diagram of voltage curves in a program phase and a validation phase of a second phase provided by an implementation of the present disclosure;

FIG. 12 is a schematic diagram of voltage application in a validation phase of a second phase provided by an implementation of the present disclosure;

FIG. 13 is a schematic diagram of voltage curves in a program phase and a validation phase of a third phase provided by an implementation of the present disclosure;

FIG. 14 is a schematic diagram of relationships between a corresponding first validation voltage and a first voltage-current relationship and a second voltage-current relationship provided by an implementation of the present disclosure;

FIG. 15 is a schematic diagram of voltage application in a compensation check operation in a third phase provided by an implementation of the present disclosure;

FIG. 16 is a schematic diagram of voltage curves in a compensation check operation in a third phase provided by an implementation of the present disclosure;

FIG. 17 is a schematic diagram of relationships between a first read voltage and a first voltage-current relationship and a second voltage-current relationship provided by an implementation of the present disclosure;

FIG. 18 is a schematic flowchart of a weight data writing process provided by an implementation of the present disclosure;

FIG. 19 is a first schematic structural diagram of an exemplary system provided by an implementation of the present disclosure;

FIG. 20 is a second schematic structural diagram of an exemplary system provided by an implementation of the present disclosure;

FIG. 21 is a schematic flowchart of an operation method of a semiconductor device provided by an implementation of the present disclosure; and

FIG. 22 is a schematic structural diagram of a computer-readable storage medium provided by an implementation of the present disclosure.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skills in the art based on the implementations in the present disclosure without creative work shall fall within the scope of protection of the present disclosure.

In the following description, numerous specific details are given in order to provide a more thorough understanding of the present disclosure. It will be apparent to those skilled in the art, however, that the present disclosure may be implemented without one or more of these details. In other examples, in order to avoid confusion with the present disclosure, some technical features known in the art are not described; that is, all features of the actual examples are not described herein, and well-known functions and structures are not described in detail.

In the drawings, the sizes of a layer, a region, and an element and their relative sizes may be exaggerated for clarity. Like reference numerals denote like elements throughout the specification.

It is to be understood that when an element or a layer is referred to as being “on,” “adjacent to,” “connected to,” or “coupled to” other elements or layers, it may be directly on, adjacent to, connected to, or coupled to the other elements or layers, or intervening elements or layers may be present. In contrast, when an element is referred to as being “directly on,” “immediately adjacent to,” “directly connected to,” or “directly coupled to” other elements or layers, no intervening elements or layers are present. It is to be understood that, although terms first, second, third and the like may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer or part discussed below may be represented as a second element, component, region, layer or part, without departing from the teachings of the present disclosure. However, when the second element, component, region, layer or part is discussed, it does not mean that the first element, component, region, layer or part is necessarily present in the present disclosure.

Spatially relative terms, such as “beneath,” “below,” “lower,” “under,” “over,” “upper,” etc., may be used here for ease of description to describe the relationship between one element or feature and other elements or features as illustrated in the figures. It is to be understood that the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terms used here are only intended to describe the specific examples, and are not used as limitations to the present disclosure. As used here, unless otherwise indicated expressly in the context, “a,” “an,” and “the” in a singular form are also intended to comprise a plural form. It should also be understood that terms “consist of” and/or “comprise,” when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

For a thorough understanding of the present disclosure, detailed operations and detailed structures will be proposed in the following description to set forth the technical solution of the present disclosure. The detailed descriptions of the preferred examples of the present disclosure are as follows. However, the present disclosure may also have other implementations in addition to these detailed descriptions.

In a classical Von Neumann computing architecture, a memory is separate from a processor, and data is transmitted through a data bus between the memory and the processor. When executing a command, the processor first reads the data from the memory, and then writes the updated data back into the memory after processing is completed, the frequent data migration causes undesirable power consumption and processing latency. In addition, since the memory bandwidth is limited, the processing speed of the processor is limited by the access speed of the memory, which greatly affects the computing performance. With the rise of applications such as big data and artificial intelligence, massive data processing makes the bottleneck of the Von Neumann computing architecture more and more prominent. In order to solve the bottleneck of the classic Von Neumann computing architecture, computing-in-memory chip architecture emerges, and the basic idea is to embed a computing function in the memory and directly use the memory to perform logic computation, thereby reducing data transmission amount and transmission distance between the memory and the processor, reducing power consumption, and improving computing performance, so that a computing system with high computing power, high bandwidth and high energy efficiency is expected to be constructed.

The computing-in-memory chip relies on its own physical characteristics while having both storage and computing abilities. The storage ability refers to the ability of different memories to store values by changing their conductance values thereof according to their physical characteristics, and the computing ability refers to the ability to complete vector matrix multiplication computation within a certain time by constructing an array composed of memory devices according to Ohm’s law and Kirchhoff’s law. The computing-in-memory includes, but is not limited to, static random access memory (SRAM), NAND flash memory, and dynamic random access memory (DRAM). NAND flash memory is a non-volatile memory and has a larger capacity, thus becoming a widely concerned object in a computing-in-memory chip. The related contents of the NAND flash memory will be correspondingly introduced as an example below.

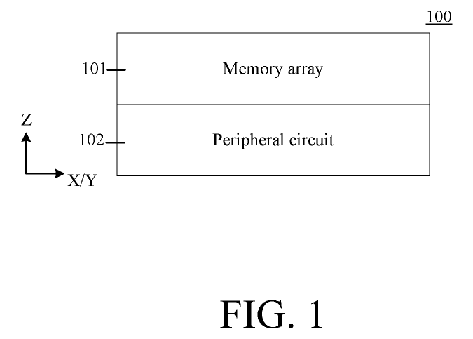

The present disclosure provides a semiconductor device. FIG. 1 is a first schematic structural diagram of a semiconductor device provided by an implementation of the present disclosure. Referring to FIG. 1, the semiconductor device 100 includes a memory array 101 and a peripheral circuit 102 coupled to the memory array 101.

In some implementations, the memory array 101 and the peripheral circuit 102 may be stacked on each other along a vertical direction (Z-axis direction shown in FIG. 1), so that a planar size of the semiconductor device may be reduced.

In some implementations, the memory array 101 and the peripheral circuit 102 may be formed in parallel on different substrates, for example, the memory array 101 is formed on a first substrate, and the peripheral circuit 102 is formed on a second substrate. They are then stacked on each other using various bonding techniques such as hybrid bonding, transfer bonding, etc. In some other implementations, the memory array 101 and the peripheral circuit 102 stacked on each other on may be sequentially formed the same substrate.

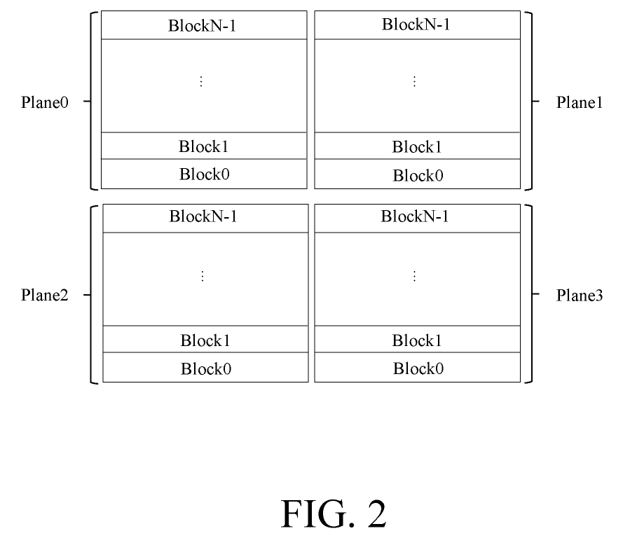

FIG. 2 exemplarily shows a second structural schematic diagram of a semiconductor device. Here, it is taken as an example for description that the semiconductor device is a three-dimensional NAND type memory. As shown in FIG. 2, a memory array may include a plurality of planes, e.g., such as Plane0, Plane1, Plane2, and Plane3, each plane may include a plurality of banks, and each bank may include a plurality of blocks.

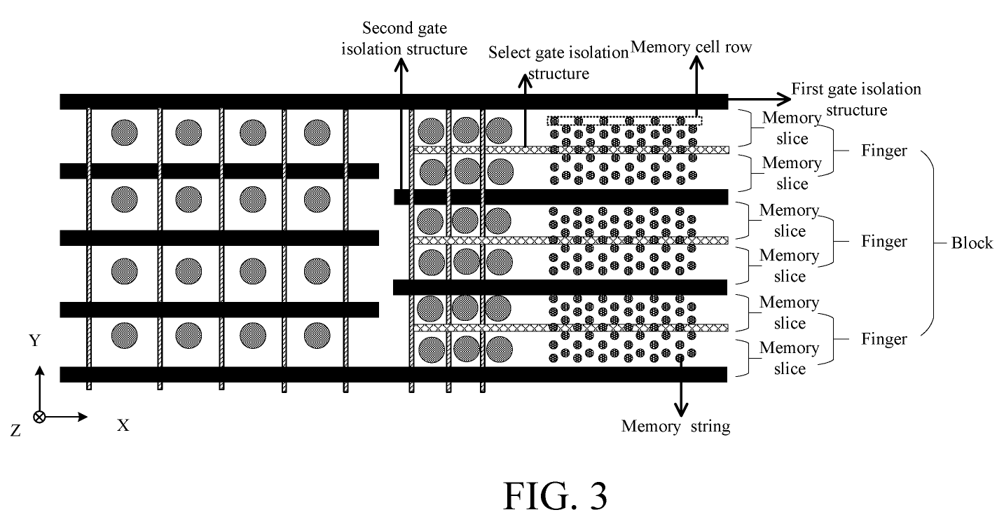

FIG. 3 exemplarily shows a schematic distribution diagram of memory cells of a semiconductor device. As shown in FIG. 3, the memory array is composed of several memory cell rows staggered and parallel to each other and parallel to a gate isolation structure, every four memory cell rows are separated by the gate isolation structure and a select gate isolation structure, each of the memory cell rows includes a plurality of memory strings arranged in X direction, one memory cell in each memory string is shown in the figure, and the remaining memory cells and this memory cell are stacked along Z direction. Here, the select gate isolation structure may be a top select gate isolation structure that divides a top select gate into a plurality of top select lines. The select gate isolation structure may also be a bottom select gate isolation structure that divides a bottom select gate into a plurality of bottom select lines. The gate isolation structure may include a first gate isolation structure and a second gate isolation structure, the first gate isolation structure divides the memory array into a plurality of blocks, the plurality of second gate isolation structures may divide the block into a plurality of fingers, and the select gate isolation structure disposed in the middle of each finger may divide the finger into two parts, thereby dividing the finger into two memory slices. One block shown in FIG. 3 includes 6 memory slices, and in some implementations, the number of memory slices in one block is not limited thereto. FIG. 3 exemplarily shows only one block of the semiconductor device, but the semiconductor device includes a plurality of blocks as shown in FIG. 3, adjacent blocks are separated by the first gate isolation structure, and the plurality of blocks may be arranged along Y direction.

It should be noted that the number of memory cell rows between the gate isolation structure and the select gate isolation structure shown in FIG. 3 is merely an example, and is not intended to limit the number of memory cell rows included in one finger of the three-dimensional NAND type memory in the present disclosure. In some implementations, the number of memory cell rows included in one finger may be adjusted according to the actual situation, such as 2, 4, 8, 16, etc.

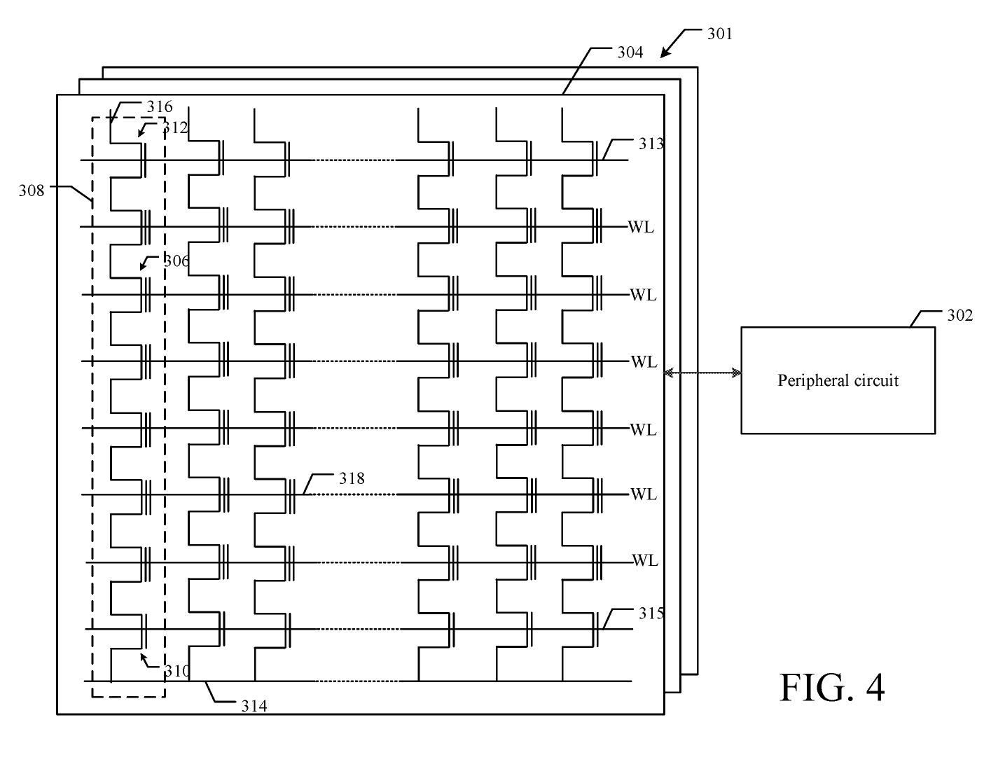

FIG. 4 is a schematic diagram of an exemplary semiconductor device including a peripheral circuit provided by an example of the present disclosure. The semiconductor device may include a memory array 301 and a peripheral circuit 302 coupled to the memory array 301. It is taken as an example for description that the memory array 301 is a three-dimensional NAND-type memory array, where a memory cell 306 is a NAND memory cell, the memory cell 306 is provided in the form of an array of memory strings 308, and each memory string 308 extends vertically. In some implementations, each memory string 308 includes a plurality of memory cells 306 coupled in series and stacked vertically. Each memory cell 306 may maintain a continuous analog value, e.g., voltage or charge, depending on the number of electrons captured within the area of the memory cell 306. Each memory cell 306 may be a floating gate type memory cell including a floating gate transistor, or a charge-trapping type memory cell including a charge trapping transistor.

In some implementations, each memory cell 306 is a single level cell (SLC) having two possible memory states and thus may store one bit of data. For example, the first memory state “0” may correspond to a first voltage range and the second memory state “1” may correspond to a second voltage range. In some implementations, each memory cell 306 is a multiple level cell capable of storing more than one bit of data in four or more memory states, e.g., a multi-level cell (MLC) storing two bits per cell, a triple level cell (TLC) storing three bits per cell, or a quad-level cell (QLC) storing four bits per cell.

As shown in FIG. 4, each memory string 308 may include a bottom select gate (BSG) 310 at its source end and a top select gate (TSG) 312 at its drain terminal. The bottom select gate 310 and the top select gate312 may be configured to activate the selected memory string 308 during read and program operations. In some implementations, the sources of the memory strings 308 in the same block 304 may be coupled through a common source line (CSL) 314. In other words, all the memory strings 308 in the same block 304 have an array common source (ACS). According to some implementations, the top select gate 312 of each memory string 308 is coupled to a corresponding bit line 316, data may be read from or written to the bit line 316 via an output bus (not shown). In some implementations, each memory string 308 is configured to be selected or deselected by applying a select voltage (e.g., a voltage higher than a threshold voltage of the top select gate 312) or a deselect voltage (e.g., 0V) to a corresponding top select gate 312 through one or more top select lines (TSL) 313 and/or by applying a select voltage (e.g., a voltage higher than a threshold voltage of the bottom select gate 310) or a deselect voltage (e.g., 0V) to a corresponding bottom select gate 310 through one or more bottom select lines (BSL) 315.

As shown in FIG. 4, the memory string 308 may be organized into a plurality of blocks 304, each of which may have a common source line 314. In some implementations, each block 304 is a basic data unit for an erase operation, e.g., all memory cells 306 on the same block 304 are erased at the same time. To erase the memory cells 306 in the selected block, a common source line 314 coupled to the selected block and an unselected block in the same plane as the selected block may be biased with an erase voltage. It should be understood that in some examples, the erase operation may be performed at a half block level, at a quarter block level, or at a level having any suitable number of blocks or any suitable fraction of block. The memory cells 306 of adjacent memory strings 308 may be coupled through a word line 318 that selects which row of memory cells 306 are affected by read and program operations.

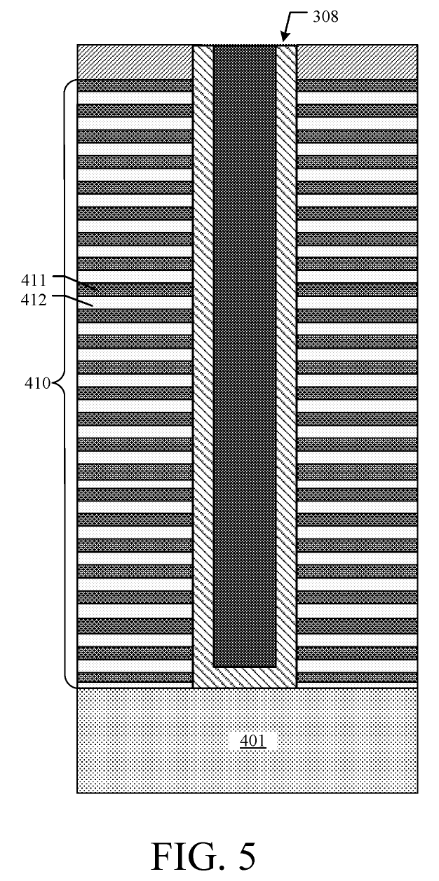

FIG. 5 shows a schematic cross-sectional view of an exemplary memory array including a memory string 308, in accordance with some aspects of the present disclosure. As shown in FIG. 5, a stack structure 410 includes a plurality of gate layers 411 and a plurality of insulating layers 412 alternately stacked in sequence, and the memory string 308 vertically extending through the gate layers 411 and the insulating layers 412. The gate layers 411 and the insulating layers 412 may be alternately stacked, and two adjacent gate layers 411 are separated by one insulating layer 412. The number of memory cells included in the memory array is mainly related to the number of pairs of gate layers 411 and insulating layers 412 in the stack structure 410.

A constituent material of the gate layer 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 includes a metal layer, such as a tungsten layer. In some implementations, each gate layer 411 includes a doped-polysilicon layer. Each gate layer 411 may include a control gate surrounding the memory cell. The gate layer 411 at the top of the stack structure 410 may extend laterally as a top select line, the gate layer 411 at the bottom of the stack structure 410 may extend laterally as a bottom select line, and the gate layers 411 extending laterally between the top select line and the bottom select line may act as word line layers.

In some implementations, the stack structure 410 may be disposed on a semiconductor layer 401. The semiconductor layer 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material. In other implementations, the semiconductor device may not include the semiconductor layer.

In some implementations, the memory string 308 includes a channel structure that extends vertically through the stack structure 410. In some implementations, the channel structure includes a channel hole filled with semiconductor material(s) (e.g., as a semiconductor channel) and dielectric material(s) (e.g., as a memory film). In some implementations, the semiconductor channel includes silicon, e.g., polysilicon. In some implementations, the memory film is a composite dielectric layer including a tunneling layer, a storage layer (also referred to as a “charge trapping/storage layer”), and a blocking layer. The channel structure may have a cylindrical shape (e.g., a pillar shape). According to some implementations, the semiconductor channel, the tunneling layer, the storage layer, and the blocking layer are arranged radially from a center of the pillar toward an outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, high-k dielectric, or any combination thereof. In one example, the memory film may include a composite layer of silicon oxide/silicon oxynitride/silicon oxide (ONO).

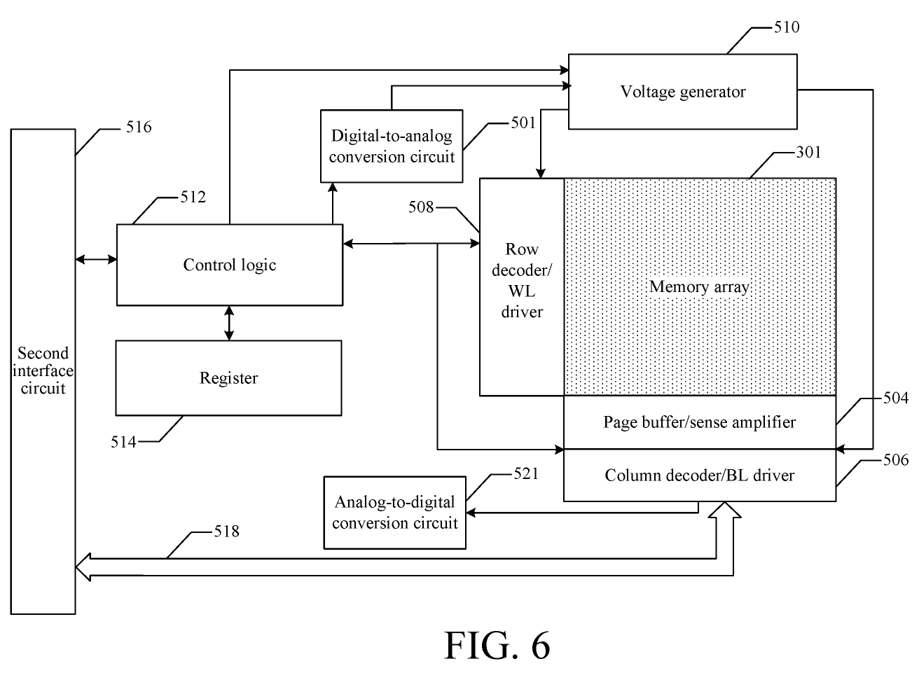

FIG. 6 is a schematic composition diagram of an exemplary semiconductor device provided by an implementation of the present disclosure, where the peripheral circuit 302 may include a digital-to-analog conversion circuit 501, a page buffer/sense amplifier 504, a column decoder/bit line driver 506, a row decoder/word line driver 508, a voltage generator 510, a control logic 512, a register 514, a second interface circuit 516, and a data bus 518. It should be understood that in some examples, additional peripheral circuits not shown in FIG. 6 may also be included. It should be noted that FIG. 6 shows an analog-to-digital conversion circuit 521, in order to further show connection relationship between the analog-to-digital conversion circuit 521 and related components of the peripheral circuit. In some implementations, the peripheral circuit includes the analog-to-digital conversion circuit 521. In some other implementations, the peripheral circuit may not include the analog-to-digital conversion circuit 521, and the analog-to-digital conversion circuit 521 and the peripheral circuit may form post-bonding connections on different wafers, respectively.

The digital-to-analog conversion circuit 501 may be coupled to the control logic 512 and the memory array 301, and the analog-to-digital conversion circuit 521 may be coupled to the column decoder/bit line driver 506. When performing an operation by using the memory array 301, the digital-to-analog conversion circuit 501 may convert a digital signal into a voltage signal required by the memory array 301, and the analog-to-digital conversion circuit 521 may convert a current signal output by the memory array 301 into digital calculation information.

The control logic 512 may be implemented in the peripheral circuit described above and couple various portions of the peripheral circuit described above, and be configured to control each operation of the peripheral circuit. The register 514 may be coupled to the control logic 512 and include a status register, a command register, and an address register for storing status information, command opcodes (OP codes), and command addresses for controlling operations of each peripheral circuit.

The page buffer/sense amplifier 504 may be configured to read data from and program (write) data to the memory array 301 according to control signals from the control logic 512. In one example, the page buffer/sense amplifier 504 may store program data (write data) to be programmed into the memory cells 306 of the memory array 301. In another example, the page buffer/sense amplifier 504 may perform a program validation operation to ensure that data has been properly programmed into the memory cells 306 coupled to a selected word line 318. The column decoder/bit line driver 506 may be configured to be controlled by the control logic 512 and to select one or more NAND memory strings 308 by applying a bit line voltage generated from the voltage generator 510.

The row decoder/word line driver 508 may be configured to be controlled by the control logic 512 and select/deselect the block 304 of the memory array 301 and select/deselect the word line 318 of the block 304. The row decoder/word line driver 508 may further be configured to drive the word line 318 using the word line voltage generated from the voltage generator 510. In some implementations, the row decoder/word line driver 508 may further select/deselect and drive the BSL 315 and the TSL 313. As described in detail below, the row decoder/word line driver 508 is configured to perform a programming operation on the memory cells 306 coupled to the selected word line(s) 318. The voltage generator 510 may be configured to be controlled by the control logic 512 and generate a word line voltage (e.g., a read voltage, a program voltage, a pass voltage, a local voltage, a validation voltage, etc., an input voltage), a bit line voltage, and a source line voltage to be supplied to the memory array 301.

In some implementations, for the computing-in-memory chip, a second operation of input data and a weight matrix needs to be implemented, the input data may be an input vector or an input matrix composed of a plurality of elements, the weight matrix is composed of a plurality of weight data, and a product accumulation operation of each element in the input data and the plurality of weight data in the weight matrix needs to be performed to obtain a corresponding element in output data.

To implement the above operation functions, the memory array 301 may be configured to store the weight matrix, and For instance, the weight data in the weight matrix may be written into the memory array 301 according to a certain mapping rule through a program operation, and the memory cells 306 in the memory array 301 may be configured to store weight data. In an operation phase, the semiconductor device may receive input data from an external device, the input data may be an input vector or an input matrix composed of a plurality of elements, and each element in the input data may be converted into an input voltage by the digital-to-analog conversion circuit, and the input voltage is input into the memory array 301 by the bit line 316 or the word line 318 or the top select line 313 or the bottom select line 315, to obtain analog calculation information.

In an implementation of the present disclosure, it is taken as an example for further description that the input voltage is input into the memory array 301 from the top select line 313 or the bottom select line 315. In an implementation of the present disclosure, the analog calculation information may be output via the bit line, or output via a source terminal. That is, the bit line of the semiconductor device is the output terminal for the analog calculation information, or the source terminal is the output terminal for the analog calculation information.

An example process of the second operation will be exemplarily described below by using example in which an input voltage is input to the memory array from the top select line and the bit line is the output terminal for the analog calculation information.

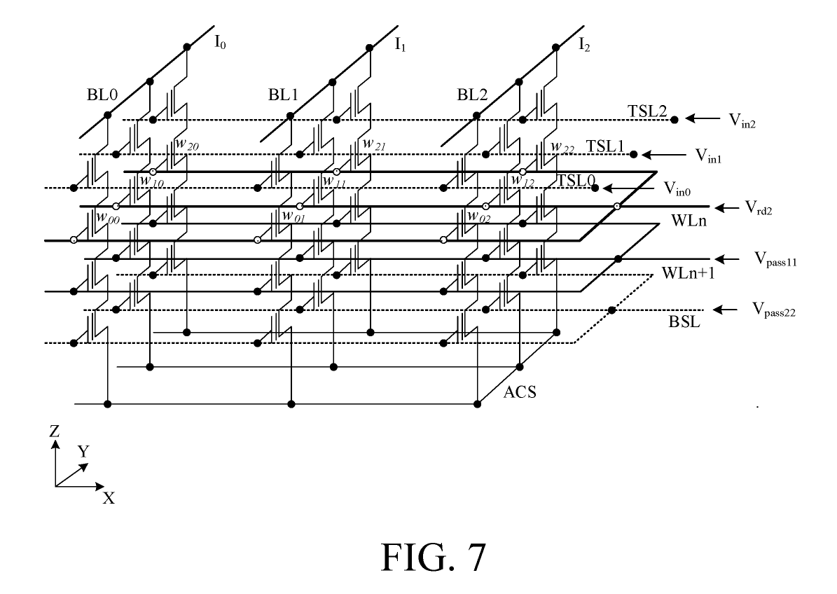

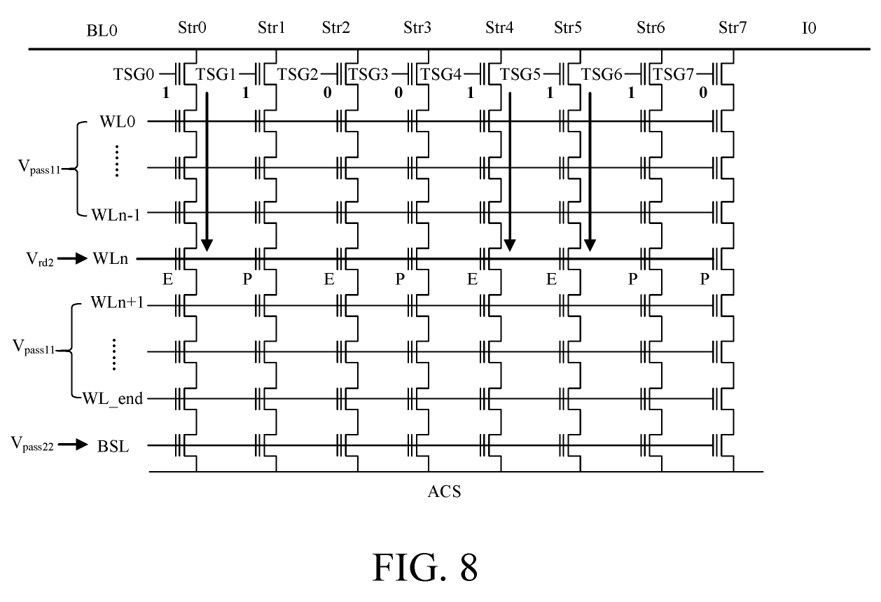

FIG. 7 is a schematic diagram of inputting an input voltage into a block from a top select line provided by an implementation of the present disclosure, and FIG. 8 is a schematic diagram of a plurality of memory strings coupled to one bit line provided by an implementation of the present disclosure. It should be noted that the number of bit lines, the number of memory strings coupled to each bit line, and the number of memory cells in each memory string shown in FIGS. 7 and 8 are merely examples, and the present disclosure does not limit the specific number of individual structures.

As shown in FIG. 7, an input voltage corresponding to an element in the input data may be input by a plurality of top select lines. In an operation phase of performing the second operation by using the memory array, the peripheral circuit is configured to: apply a second read voltage V_{rd2} to the target word line WLn coupled to the target block, and apply corresponding input voltages to a plurality of top select lines coupled to the target block, respectively. For example, the input voltages Vᵢₙ₀, Vᵢₙ₁, Vᵢₙ₂ may be respectively applied to the top select lines TSL0, TSL1, TSL2 coupled to the target block, and a first turn-on voltage may be applied to the non-target word line coupled to the target block. For example, a first turn-on voltage Vₚₐₛₛ₁₁ may be applied to a word line WLn+1, and a second turn-on voltage may be applied to the bottom select line coupled to the target block. For example, a second turn-on voltage Vₚₐₛₛ₂₂ may be applied to the bottom select line BSL. The analog calculation information may be obtained by sensing the current on the bit line coupled to the target block. For example, the sum of the product of the element corresponding to the input voltage Vᵢₙ₀ and the weight w 00, the product of the element corresponding to the input voltage Vᵢₙ₁ and the weight w 10, and the product of the element corresponding to the input voltage Vᵢₙ₂ and the weight w 20 may be obtained by sensing the current I₀ on the bit line BL0 and converting the current I₀. In some implementations, the second operation includes a product accumulation operation.

In some implementations, the peripheral circuit is configured to apply a corresponding program voltage to the target word line coupled to the target block to program memory cells coupled to the target word line before performing the second operation by using the memory array.

In some examples, a memory cell in the target block is configured to store one bit of data, a plurality of memory cells in the target block have a first memory state and a second memory state, a threshold voltage of the memory cell having the first memory state is less than a threshold voltage of the memory cell having the second memory state, the second read voltage V_{rd2} is greater than the threshold voltage of the memory cell having the first memory state, and is less than the threshold voltage of the memory cell having the second memory state. Here, the memory cell in the target block may be a single level cell SLC storing one bit of data, the first memory state may be an erased state E, and the second memory state may be a programmed state P. The peripheral circuit may be configured to perform a program operation on the memory cells coupled to the target word line before performing the second operation, write the weight data into the memory cell according to a certain mapping rule. For the single level cell, a process of writing the weight data includes applying a corresponding program voltage to adjust a threshold voltage of a portion of the memory cells coupled to the target word line to be within a range of a threshold voltage distribution corresponding to the second memory state.

In some implementations, as shown in FIG. 8, it is taken as an example that the target block includes eight memory strings coupled to the bit line BL0, four of the memory cells coupled to the target word line WLn are in the first memory state (the erased state E), the other four memory cells are in the second memory state (the programmed state P), the input data may be input from the eight top select lines TSL0 to TSL7. For instance, the input data may be an input vector including eight elements that may include five “1” and three “0,” the digital-to-analog conversion circuit may convert each element of the input vector into a corresponding voltage signal, and convert the voltage signal into an input voltage that needs to be applied to the top select line through the voltage generator, and transfer the input voltage to the top select line through a driver coupled to the top select line. For instance, eight input voltages may be simultaneously applied to the eight top select lines, respectively. The input voltage corresponding to “1” includes Vᵢₙ₀, Vᵢₙ₁, Vᵢₙ₄, Vᵢₙ₅, and Vᵢₙ₆, so that the top select gates TSG 0, TSG 1, TSG 4, TSG 5 and TSG 6 coupled to the top select lines TSL0, TSL1, TSL4, TSL5, and TSL6, respectively, may be turned on, and the input voltage corresponding to “0” includes Vᵢₙ₂, Vᵢₙ₃, Vᵢₙ₇, so that the top select gates TSG2, TSG 3, and TSG 7 coupled to the top select lines TSL2, TSL3, and TSL7, respectively, may be turned off.

In some examples, as shown in FIG. 8, the current I₀ on the bit line BL0 is the sum of the output currents of the eight memory strings coupled to the bit line BL0, where the input voltage on the top select line coupled to the memory strings Str0, Str4 and Str5 causes the top select gates TSG0, TSG4 and TSG 5 to be in the turn-on state, and the memory cells in the memory strings Str0, Str4 and Str5 coupled to the target word line WLn have the first memory state (the erased state E), so the memory strings Str0, Str4, and Str5 are turned on, currents greater than or equal to a preset current may be generated, the currents I₀ on the bit line BL0 is substantially equal to the sum of the output currents of the memory strings Str0, Str4 and Str5, and the multiple of the current I₀ relative to the current generated by any one of the memory strings Str0, Str4 and Str5 is approximately equal to 3. If the weight value stored in the memory cell in the first memory state is equivalent to “1,” and the weight value stored in the memory cell in the second memory state is equivalent to “0,” the operations performed by the eight memory strings coupled to the bit line BL0 may be equivalent to: 1*1+1*0+0*1+0*0+1*1+1*1+1*0+0*0=3.

Based on the foregoing example, when there are Y+1 memory strings coupled to the bit line BLx in the target block, Y+1 elements corresponding to input voltages input by Y+1 top select lines are α 0 , α 1,..., α Y, respectively, and the weights stored in Y+1 memory cells coupled to the target word line WLn are w 0 , w 1,..., w Y, respectively, then the analog calculation information equivalent to a multiple of the current on the bit line BLx relative to the output current greater than or equal to the preset current may be α 0* w 0 +α 1* w 1 +···+α Y* w Y.

In an implementation of the present disclosure, when the second operation is needs to be performed by using a plurality of banks, the first turn-on voltage may be applied to the non- target word lines in the plurality of banks simultaneously, so that voltage establishment phases of the first turn-on voltage applied to the non-select word lines coupled to different banks may be overlapped. Compared with a manner of applying the first turn-on voltage to the non-select word lines coupled to different banks respectively during different operation phases, overall operation time can be shortened, and operation efficiency of performing the second operation by using a plurality of banks can be improved.

Further, for each bank, the second operation may be performed by using the plurality of blocks in the bank simultaneously, and the peripheral circuit may be configured to: apply the second read voltage to the target word lines individually coupled to the plurality of blocks in the bank respectively; apply the corresponding input voltage to the plurality of top select lines individually coupled to the plurality of blocks in the bank respectively; and obtain currents on the bit lines coupled to the plurality of blocks in the bank. For instance, the second read voltage V_{rd2} may be applied to the target word lines individually coupled to the plurality of blocks Block0 to BlockN in the bank Bank0 simultaneously; meanwhile, the corresponding input voltage Vᵢₙ may be applied to the plurality of top select lines individually coupled to the plurality of blocks Block0 to BlockN, and the current on the bit line coupled to the plurality of blocks Block0 to BlockN may be obtained, and the current on the bit line is the analog calculation information after all the memory strings coupled to the bit line perform the second operation. Therefore, the plurality of blocks can perform the second operation in parallel, so that the operation efficiency and the computing power of the semiconductor device can be further improved.

In order to ensure sufficient computing-in-memory computing accuracy, the distribution of summed current on the bit line may be kept narrow, and currents flowing through individual memory cells may be different; improving the computing-in-memory computing accuracy in the process of performing the second operation in the foregoing implementations by using the memory array becomes an urgent problem to be solved in the current stage.

An implementation of the present disclosure provides a semiconductor device. Referring to FIG. 1, the semiconductor device 100 includes the memory array 101 and the peripheral circuit 102 coupled to the memory array 101; the memory array 101 includes a plurality of memory cells, and the peripheral circuit 102 is configured to: in a first phase, perform a first program operation on a first memory cell coupled to a first word line in a first word line group; in a second phase, perform a second program operation on a second memory cell coupled to a second word line in a second word line group, to write the weight data into the second memory cell; and in a third phase, perform a third program operation on a third memory cell coupled to a third word line in the first word line group; and in the third phase, apply a first read voltage to a fourth word line in a third word line group, to obtain the current of the bit line coupled to the third memory cell; and the first phase, the second phase, and the third phase all precede the operation phase.

In an implementation of the present disclosure, the second program operation is performed on the second memory cell coupled to the second word line in the second word line group in the second phase, so that the weight data is written into the second memory cell; the first program operation is performed on the first memory cell coupled to the first word line in the first word line group in the first phase, to compensate for a current of a memory string to which the first memory cell belongs in the operation phase; and the third program operation is performed on the third memory cell coupled to the third word line in the first word line group in the third phase, and the first read voltage is applied to the fourth word line in the third word line group in the third phase to obtain the current of the bit line coupled to the third memory cell, to further compensate for the current of the memory string in the operation phase. According to schemes provided by implementations of the present disclosure, the current of the memory string in the operation phase is subjected to a preliminary compensation and a further fine compensation before the operation phase, so that the deviation of currents of individual memory strings in the operation phase can be reduced, the current distribution in the computing-in-memory process of the semiconductor device is narrowed, thus the computing-in-memory accuracy can be improved.

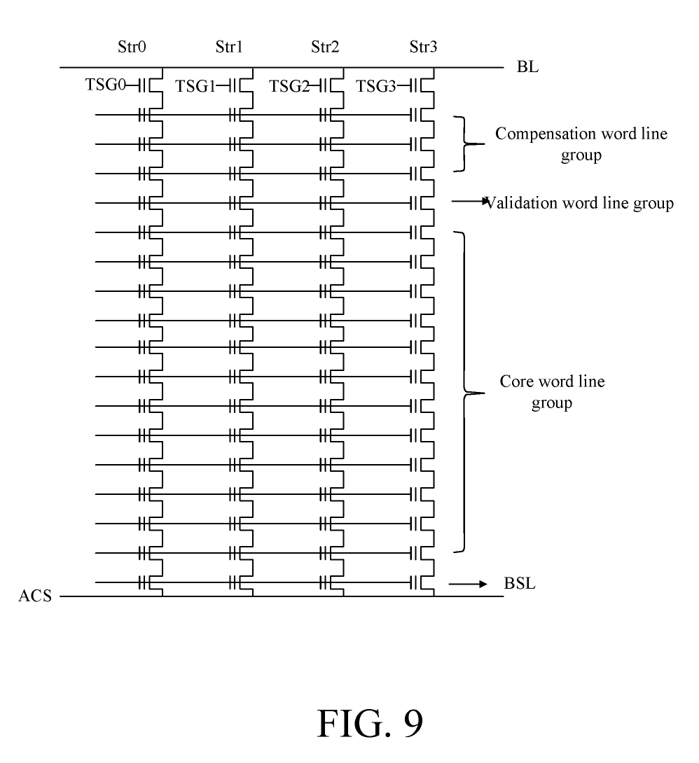

In an implementation of the present disclosure, as shown in FIG. 9, the same bit line is coupled to a plurality of memory strings (e.g., Str1-Str3), and a plurality of word lines in the memory array 101 are divided into a compensation word line group including a plurality of compensation word lines, a validation word line group, and a core word line group including a plurality of core word lines. In an implementation of the present disclosure, the first word line group may be the compensation word line group shown in FIG. 9, the second word line group may be the core word line group shown in FIG. 9, and the third word line group may be the validation word line group shown in FIG. 9.

In some implementations, the validation word line group is located between the first word line group and the second word line group. It should be noted that, in FIG. 9, the compensation word line group is located between the top select line and the validation word line group, the validation word line group is located between the compensation word line group and the core word line group, and the core word line group is located between the bottom select line and the validation word line group, but is not used to limit location relationship among the compensation word line group, the core word line group, the validation word line group, the top select line, and the bottom select line in the implementations of the present disclosure. In some implementations, the first word line group is located between the validation word line group and the second word line group. In further implementations, the second word line group is located between the first word line group and the validation word line group.

In an implementation of the present disclosure, the first word line may be any compensation word line in the compensation word line group; the second word line may be any core word line in the core word line group; the third word line may be any compensation word line in the compensation word line group, and the third word line is different from the first word line; and the fourth word line may be any validation word line in the validation word line group. In an implementation of the present disclosure, the memory cells coupled to the core word line are configured to store the weight data, the memory cells coupled to the compensation word line group and the validation word line are not configured to store the weight data, and the memory cells coupled to the compensation word line group are only configured to compensate for the current of the memory string in the operation phase.

In some implementations, the core word line group includes a plurality of core word lines, the compensation word line group includes a plurality of compensation word lines, and the validation word line group may include only one word line, but the present disclosure is not limited thereto.

In an implementation of the present disclosure, in the first phase and the third phase, only memory cells coupled to a part of the word lines in the core word line group are programmed, and memory cells coupled to another part of the word lines in the core word line group may not be programmed.

In some implementations, memory cells in the memory array 101 are configured to have an erase state and a program state; the memory cells in the erase state correspond to a first voltage-current relationship, and the memory cells in the program state correspond to a second voltage-current relationship.

In an implementation of the present disclosure, the memory cells in the memory array may be configured to have multiple memory states, and after different voltages are applied to a word line coupled to memory cells in a corresponding memory state, the bit line coupled to the memory cells in the memory state is pre-charged to a target voltage, and the current of the bit line coupled to the memory cells in the memory state is obtained, so that voltage-current relationship in the memory state may be obtained.

For example, the first voltage-current relationship may be obtained by applying different voltages to a word line coupled to memory cells in the erase state, pre-charging the bit line coupled to the memory cells in the erase state to the target voltage, and obtaining the current of the bit line coupled to the memory cells in the erase state.

For example, the second voltage-current relationship may be obtained by applying different voltages to a word line coupled to memory cells in a program state, pre-charging the bit line coupled to the memory cells in the program state to the target voltage, and obtaining the current of the bit line coupled to the memory cells in the program state.

In some implementations, the peripheral circuit 102 is configured to: apply a first validation voltage to the first word line in a validation phase of the first program operation; apply a second validation voltage to the second word line in a validation phase of the second program operation; apply a third validation voltage to the third word line in a validation phase of the third program operation; a threshold voltage of the first memory cell after the first program operation is performed on the first memory cell is a first threshold voltage, and a threshold voltage of the third memory cell after the third program operation is performed on the third memory cell is a second threshold voltage; the first validation voltage is different from the third validation voltage; or the first threshold voltage is different from the second threshold voltage.

It can be understood that, in an implementation of the present disclosure, during the first program operation and the third program operation, a corresponding validation voltage applied, a threshold voltage of a memory cell after a program operation, a corresponding turn-on voltage applied on an unselected word line, and a bit line voltage applied on a selected bit line are involved, and by adjusting one or more of the above-mentioned voltages in the first program operation and the third program operation, the first validation voltage applied in the first program operation corresponds to a voltage in a linear region in the second voltage-current relationship, and the third validation voltage applied in the third program operation corresponds to a voltage in a transition region in the second voltage-current relationship.

Hereinafter, it is taken as an example for exemplary description that one of the above-mentioned four voltages in the first program operation and the third program operation is maintained to be different, and the other three voltages are the same.

In some implementations, the first threshold voltage is different from the second threshold voltage, and the first validation voltage is equal to the third validation voltage.

When the first validation voltage is equal to the third validation voltage, corresponding turn-on voltages applied on an unselected word line in the first program operation and the third program operation are equal, bit line voltages applied on the selected bit line in the first program operation and the third program operation are equal, and the first threshold voltage is different from the second threshold voltage, so that the first validation voltage applied in the first program operation corresponds to the voltage in the linear region in the second voltage-current relationship, and the third validation voltage applied in the third program operation corresponds to the voltage in the transition region in the second voltage-current relationship. In the foregoing implementations, when the first validation voltage is the same as the third validation voltage, voltages come from a common source, so that circuits can be simplified.

In some implementations, the first validation voltage is different from the third validation voltage, and the first threshold voltage is equal to the second threshold voltage.

When the first threshold voltage is equal to the second threshold voltage, corresponding turn-on voltages applied on an unselected word line in the first program operation and the third program operation are equal, bit line voltages applied on the selected bit line in the first program operation and the third program operation are equal, and the first validation voltage is different from the third validation voltage, so that the first validation voltage applied in the first program operation corresponds to the voltage in the linear region in the second voltage-current relationship, and the third validation voltage applied in the third program operation corresponds to the voltage in the transition region in the second voltage-current relationship.

In some implementations, the first validation voltage is greater than the third validation voltage, and the first threshold voltage is equal to the second threshold voltage.

When the other three voltages are equal, the first validation voltage is greater than the third validation voltage, so that the first validation voltage applied in the first program operation corresponds to the voltage in the linear region in the second voltage-current relationship, and the third validation voltage applied in the third program operation corresponds to the voltage in the transition region in the second voltage-current relationship.

In some implementations, memory cells in the memory array are configured to have an erase state; the memory cells in the erase state correspond to first voltage-current relationship, and the memory cells in the program state correspond to second voltage-current relationship; a second current is a current in the linear region in the second voltage-current relationship, and a third current is a current in the transition region in the second voltage-current relationship; the first validation voltage is voltage corresponding to the second current in the second voltage-current relationship; and the third validation voltage is voltage corresponding to the third current in the second voltage-current relationship.

In some implementations, the first validation voltage may also be less than the third validation voltage. For example, two or more of the above four voltages may be set differently, so that the first validation voltage applied in the first program operation corresponds to the voltage in the linear region in the second voltage-current relationship, and the third validation voltage applied in the third program operation corresponds to the voltage in the transition region in the second voltage-current relationship.

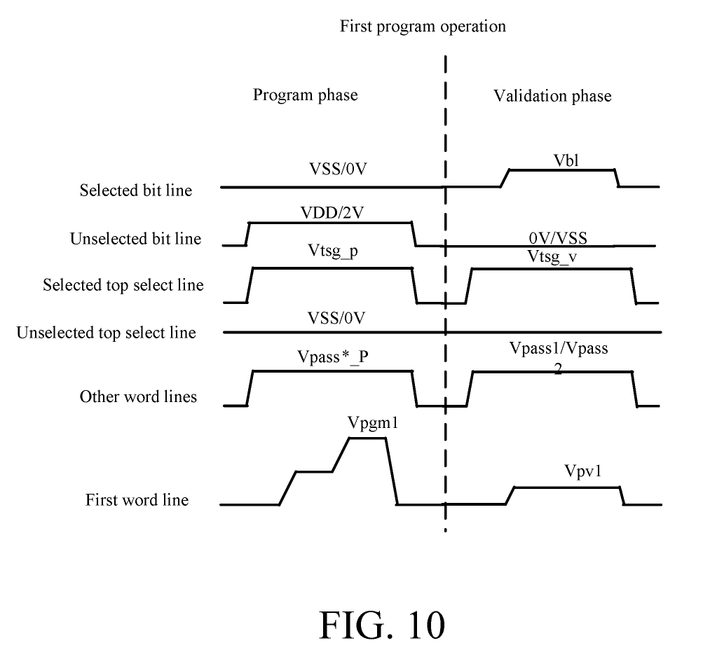

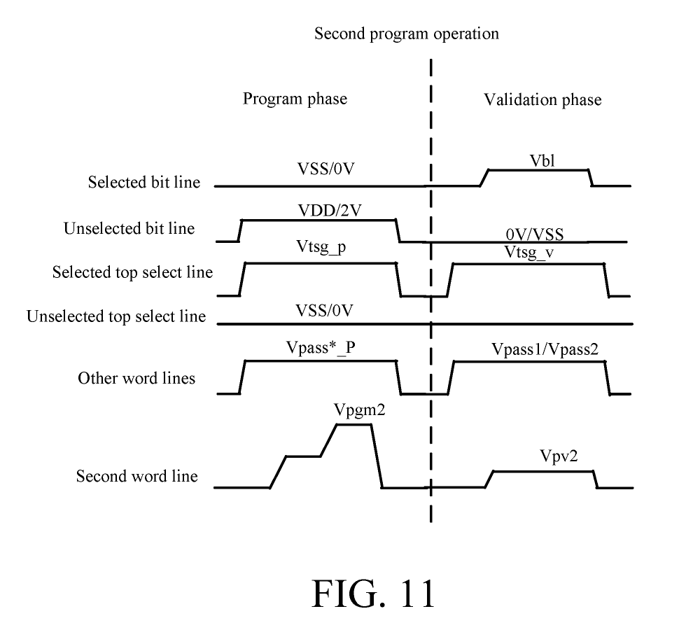

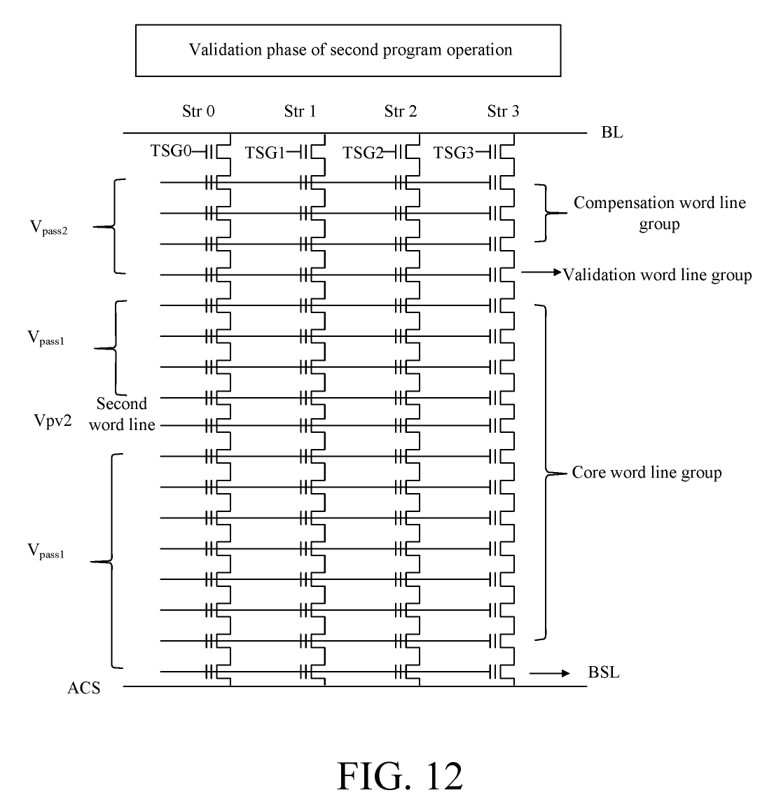

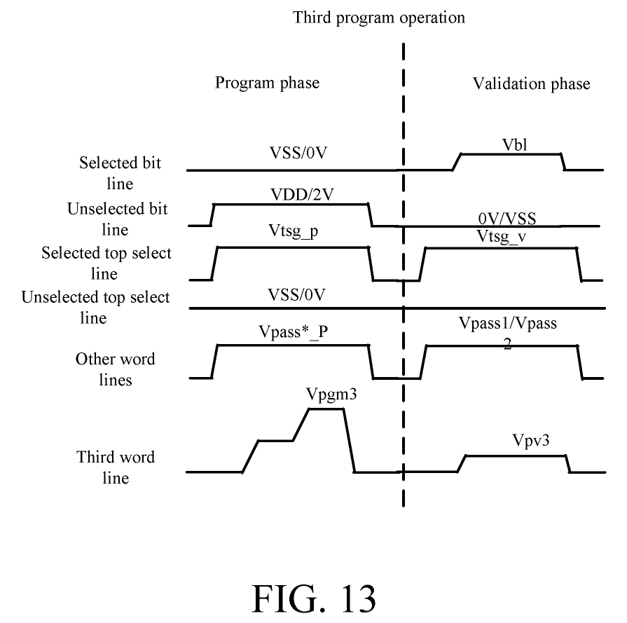

FIG. 10 is a schematic diagram of voltage curves in the program phase and the validation phase of the first phase provided by an implementation of the present disclosure; FIG. 11 is a schematic diagram of voltage curves in the program phase and the validation phase of the second phase provided by an implementation of the present disclosure; FIG. 12 is a schematic diagram of voltage application in the validation phase of the second phase provided by an implementation of the present disclosure; and FIG. 13 is a schematic diagram of voltage curves in the program phase and the validation phase of the third phase provided by an implementation of the present disclosure.

As shown in FIG. 10, in the validation phase of the first phase, a first validation voltage Vpv1 is applied to a first word line; as shown in FIGS. 11 and 12, in the validation phase of the second phase, a second validation voltage Vpv2 is applied to a second word line; and as shown in FIG. 13, in the validation phase of the third phase, a third validation voltage Vpv3 is applied to a third word line. In some implementations, the first validation voltage, the second validation voltage, and the third validation voltage may be the same or different.

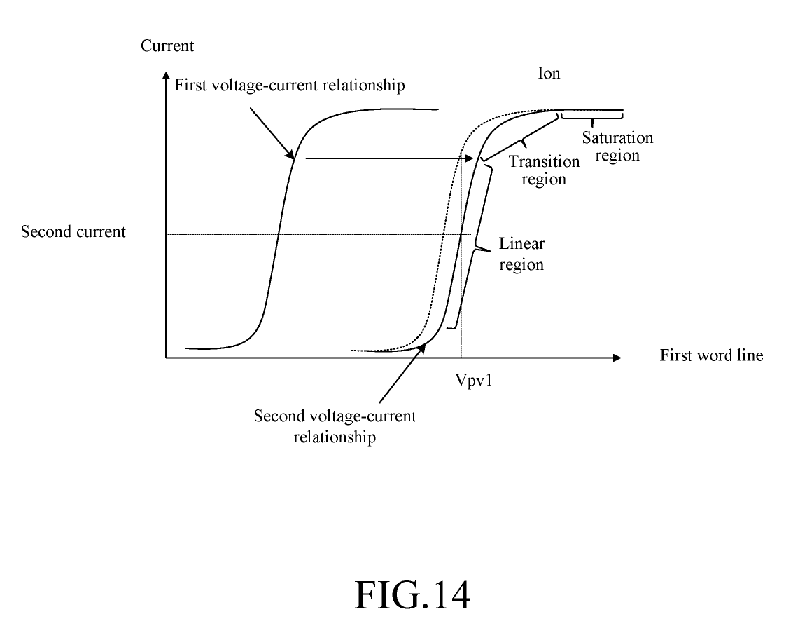

FIG. 14 is a schematic diagram of relationship between a corresponding first validation voltage Vpv1 and the first voltage-current relationship and the second voltage-current relationship provided by an implementation of the present disclosure. As shown in FIG. 14, Vpv1 is a voltage corresponding to second current in the second voltage-current relationship, the second current is the current in the linear region in the second voltage-current relationship, and the second current is also the current in the linear region in the first voltage-current relationship.

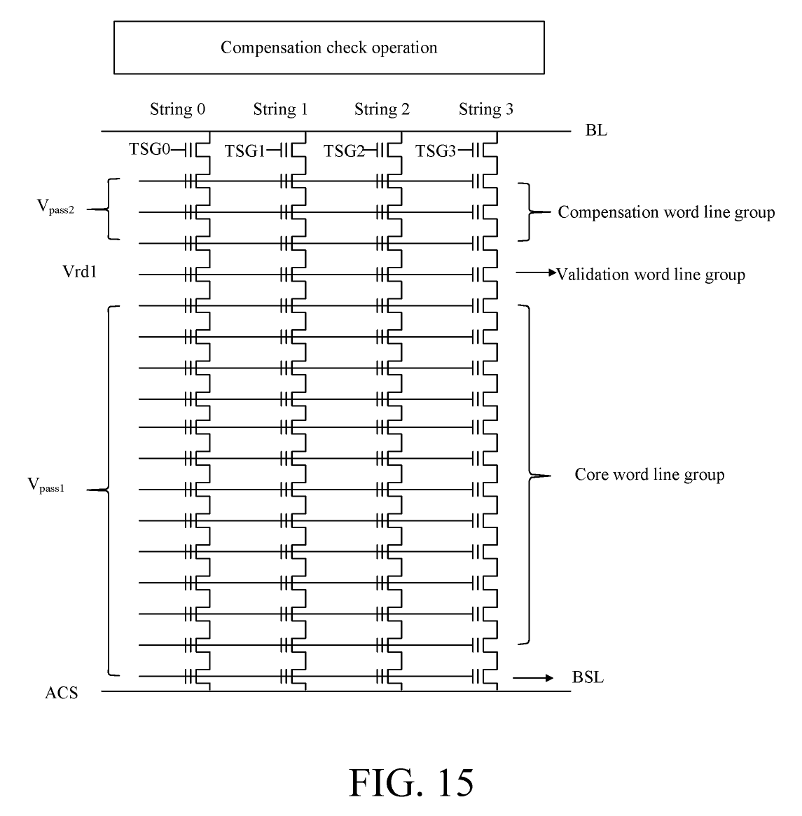

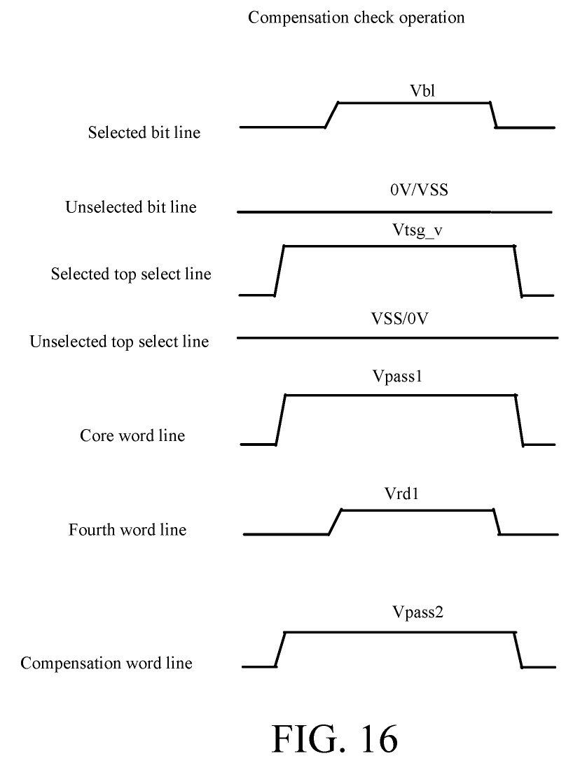

FIG. 15 is a schematic diagram of voltage application in a compensation check operation of the third phase provided by an implementation of the present disclosure; and FIG. 16 is a schematic diagram of voltage curves in the compensation check operation in the third phase provided by an implementation of the present disclosure. As shown in FIGS. 15 and 16, in the compensation check operation in the third phase, the first read voltage Vrd1 is applied to the fourth word line (the validation word line).

Here, the compensation check operation includes applying the first read voltage to the fourth word line to obtain the current of the bit line coupled to the third memory cell mentioned in the above implementations.

In some implementations, the peripheral circuit 102 is configured to: apply corresponding turn-on voltages to the top select line and the bottom select line coupled to the third memory cell, and word lines other than the fourth word line, respectively, during a same period of applying the first read voltage to the fourth word line.

In some implementations, as shown in FIGS. 15 and 16, the peripheral circuit 102 is configured to: apply a ground voltage VSS/0V to an unselected bit line, apply a corresponding turn-on voltage Vpass2 to the compensation word line, apply a corresponding turn-on voltage Vpass1 to the core word line, apply a corresponding turn-on voltage Vtsg_v to the top select line (selected top select line) coupled to the third memory cell, apply a ground voltage VSS/0V to an unselected top select line, and apply a bit line voltage Vbl to the bit line (the selected bit line) coupled to the third memory cell.

In some implementations, a first current is current in a saturation region in the first voltage-current relationship, the first read voltage is a voltage corresponding to the first current in the first voltage-current relationship, and the first read voltage is less than the voltage in the linear region in second voltage-current relationship.

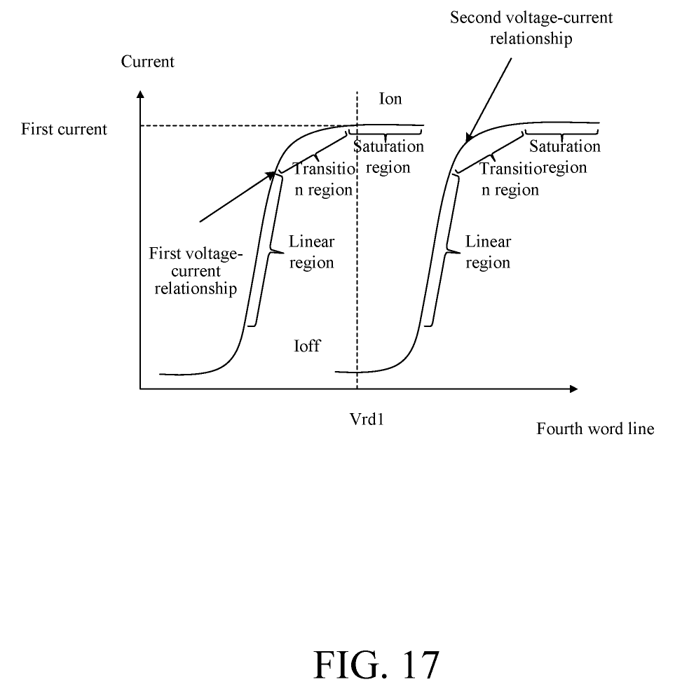

FIG. 17 is a schematic diagram of relationship between the first read voltage Vrd1 and first voltage-current relationship and second voltage-current relationship provided by an implementation of the present disclosure. As shown in FIG. 17, Vrd1 is a voltage corresponding to the first current in the first voltage-current relationship, the first current is the current in the saturation region in the first voltage-current relationship, and the first read voltage is less than the voltage in the linear region in the second voltage-current relationship.

In some implementations, the peripheral circuit 102 is configured to: apply a corresponding program voltage Vpgm1 to the first word line and apply the ground voltage VSS/0V to the bit line (the selected bit line) coupled to the first memory cell, in the program phase of the first program operation, as shown in FIG. 10; apply a corresponding program voltage Vpgm2 to the second word line and apply the ground voltage VSS/0V to the bit line (the selected bit line) coupled to the second memory cell, in the program phase of the second program operation, as shown in FIG. 11; and apply a corresponding program voltage Vpgm3 to the third word line and apply the ground voltage VSS/0V to the bit line (the selected bit line) coupled to the third memory cell, in the program phase of the third program operation, as shown in FIG. 13.

In some implementations, as shown in FIG. 10, the peripheral circuit 102 is configured to: in the program phase of the first program operation, apply a power voltage VDD/2V to the unselected bit line, apply a corresponding turn-on voltage Vpass*_P to word lines other than the first word line, apply a corresponding turn-on voltage Vtsg_p to the top select line (the selected top select line) coupled to the first memory cell, and apply the ground voltage VSS/0V to the unselected top select line.

As shown in FIG. 11, the peripheral circuit 102 is configured to: in the program phase of the second program operation, apply the power voltage VDD/2V to the unselected bit line, apply the corresponding turn-on voltage Vpass*_P to word lines other than the second word line, apply the corresponding turn-on voltage Vtsg_p to the top select line (the selected top select line) coupled to the second memory cell, and apply the ground voltage VSS/0V to the unselected top select line; as shown in FIG. 13, the peripheral circuit 102 is configured to: in the program phase of the third program operation, apply the power voltage VDD/2V to the unselected bit line, apply the corresponding turn-on voltage Vpass*_P to word lines other than the third word line, apply the corresponding turn-on voltage Vtsg_p to the top select line (the selected top select line) coupled to the third memory cell, and apply the ground voltage VSS/0V to the unselected top select line.

In some implementations, as shown in FIG. 10, the peripheral circuit 102 is configured to: in the validation phase of the first program operation, apply the ground voltage VSS/0V to the unselected bit line, apply the corresponding turn-on voltage Vpass1/Vpass2 to word lines other than the first word line, apply the corresponding turn-on voltage Vtsg_v to the top select line (the selected top select line) coupled to the first memory cell, apply the ground voltage VSS/0V to the unselected top select line, and apply the bit line voltage Vbl to the bit line (the selected bit line) coupled to the first memory cell.

As shown in FIG. 11, the peripheral circuit 102 is configured to: in the validation phase of the second program operation, apply the ground voltage VSS/0V to the unselected bit line, apply the corresponding turn-on voltage Vpass1/Vpass2 to word lines other than the second word line, apply the corresponding turn-on voltage Vtsg_v to the top select line (the selected top select line) coupled to the second memory cell, apply the ground voltage VSS/0V to the unselected top select line, and apply the bit line voltage Vbl to the bit line (the selected bit line) coupled to the second memory cell.

As shown in FIG. 13, the peripheral circuit 102 is configured to: in the validation phase of the third program operation, apply the ground voltage VSS/0V to the unselected bit line, apply the corresponding turn-on voltage Vpass1/Vpass2 to word lines other than the third word line, apply the corresponding turn-on voltage Vtsg_v to the top select line (the selected top select line) coupled to the third memory cell, apply the ground voltage VSS/0V to the unselected top select line, and apply the bit line voltage Vb1 to the bit line (the selected bit line) coupled to the third memory cell.

It should be noted that the first phase, the second phase, and the third phase all precede the operation phase, but the sequential relationship among the first phase, the second phase, and the third phase is not limited in implementations of the present disclosure.

For example, the first phase may be performed first, then the second phase may be performed, and finally the third phase may be performed; the first phase may be performed first, then the third phase may be performed, and finally the second phase may be performed; or the second phase may be performed first, then the first phase may be performed, and finally the third phase may be performed.

In some implementations, the second phase follows the first phase and the third phase follows the second phase.

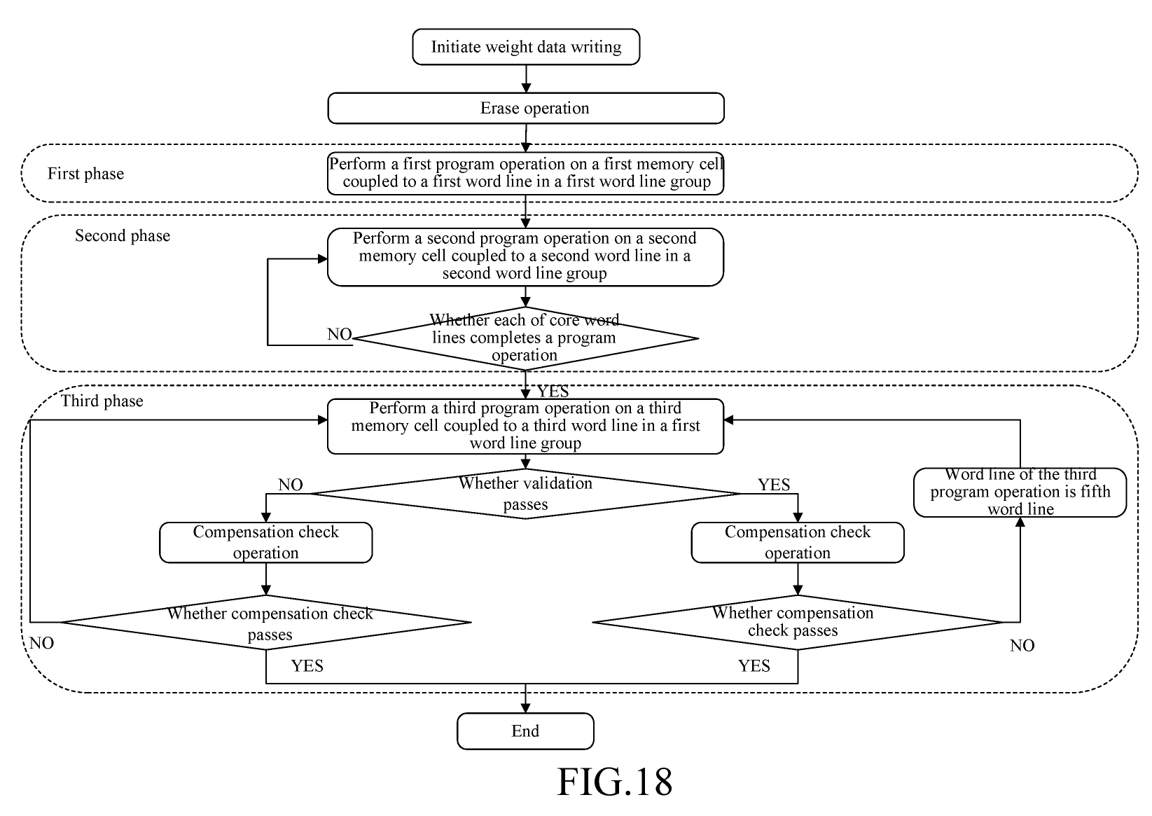

FIG. 18 is a schematic flowchart of a weight data writing process according to an implementation of the present disclosure. Hereinafter, it is taken as an example for further description in conjunction with FIG. 18 that the first phase is performed first, then the second phase is performed, and finally the third phase is performed.

As shown in FIG. 18, after starting to initiate weight data writing, in some implementations, the peripheral circuit 102 is configured to: perform an erase operation on each of the memory cells of the memory array before the first phase, the second phase, and the third phase.

In an implementation of the present disclosure, before the first phase, the second phase, and the third phase start, the erase operation is performed on each of the memory cells, so that each of the memory cells in the memory array are in the erase state.

As shown in FIG. 18, after the erase operation is performed, the first phase described in the foregoing implementations is performed, the first program operation is performed on the first memory cell coupled to the first word line, and the compensation word line group may include a plurality of first word lines.

In the first phase, the first program operation may be performed on first memory cells coupled to a part of the first word lines in the compensation word line group, and the first validation voltage applied in the first program operation corresponds to the voltage in the linear region in the second voltage-current relationship.

After the first phase is completed, the second phase described in the foregoing implementations is performed, and the second program operation is performed on the second memory cell coupled to the second word line, where the second word line is the core word line, and the weight data is written into the memory cell coupled to the core word line; and after all the memory cells coupled to the core word line complete writing of the weight data, the third phase described in the foregoing implementations is performed.

In an implementation of the present disclosure, in the first phase, threshold voltages of the memory cells coupled to a par of the compensation word lines are increased, the process deviation between the memory strings is handled, and an on-state current (Ion) of each memory string is lowered to an intermediate level, thereby improving the influence of processes and patterns on the writing process of the weight data of the memory cells coupled to the core word lines and the caused loss of accuracy.

In some implementations, in the third phase, the peripheral circuit 102 is configured to pre-charge a sensing node coupled to the bit line coupled to the third memory cell to the target voltage.

Here, pre-charging the sensing node coupled to the bit line coupled to the third memory cell to the target voltage may be performed in the compensation check operation phase, and by pre-charging the sensing node coupled to the bit line coupled to the third memory cell to the target voltage, and applying the first read voltage to the fourth word line to obtain the current of the bit line coupled to the third memory cell, the on-state current of the memory string after weight data writing and two-step compensation may be obtained, and whether the on-state current of the memory string needs to be further compensated may be determined according to the on-state current of the memory string.

In some implementations, the peripheral circuit 102 is configured to: perform the third program operation on a memory cell belonging to the third memory cell among memory cells coupled to a fifth word line in response to the third memory cell passing a validation and the current of the bit line coupled to the third memory cell exceeding the preset range; or continue to perform the third program operation on the third memory cell in response to the third memory cell failing the validation and the current of the bit line coupled to the third memory cell exceeding the preset range.

In some implementations, the first memory cell, the second memory cell, and the third memory cell may belong to the same memory string.

It can be understood that the first program operation may be performed on the first memory cell belonging to the same memory string in the first phase, and after the second program operation is performed on the second memory cell in the same memory string in the second phase, whether the current of the bit line coupled to the memory string exceeds the preset range is checked through the compensation check operation. If the current of the bit line coupled to the memory string exceeds the preset range, the third program operation may be performed on the third memory cell in the memory string to further compensate for the current of the bit line coupled to the memory string.

In some implementations, the first memory cell and the third memory cell may also belong to different memory strings.

It can be understood that the first program operation may be performed on the first memory cell in a certain memory string in the first phase, and after the second program operation is performed on the second memory cell in that memory string in the second phase, whether the current of the bit line coupled to the memory string exceeds the preset range is checked through the compensation check operation. If the current of the bit line coupled to the memory string does not exceed the preset range, further compensation may not be performed on the current of the bit line coupled to the memory string, and the third program operation is performed on the third memory cell in another memory string in the third phase to further compensate the current of the bit line coupled to the another memory string.

In some implementations, the third memory cell and the first memory cell are located on the same side of two opposite sides of the second memory cell along the vertical direction, where the vertical direction may be understood as an extending direction of the memory string. The third memory cell may be located between the first memory cell and the second memory cell, or the first memory cell may be located between the second memory cell and the third memory cell, which is not limited in the present disclosure.

In some implementations, the second memory cell may be located between a source line and the first memory cell/the third memory cell.

As shown in FIG. 18, in the third phase, the third program operation is performed on the third memory cell coupled to the third word line, the third validation voltage applied in the third program operation corresponds to the voltage in the transition region in the second voltage-current relationship, and whether the third memory cell passes the validation is determined through the validation operation in the third program operation; and the compensation check operation is performed in the third phase, where the compensation check operation may include: applying the first read voltage to the fourth word line, and pre-charging the sensing node coupled to the bit line coupled to the third memory cell to the target voltage to determine whether a compensation check of the memory string to which the third memory cell belongs passes; when the current of the bit line coupled to the memory string to which the third memory cell belongs exceeds the preset range, it is determined that the compensation check of that memory string fails; and when the current of the bit line coupled to the memory string to which the third memory cell belongs does not exceed the preset range, it is determined that the compensation check of that memory string passes.

As shown in FIG. 18, regardless of whether the third memory cell passes the validation, the compensation check operation is performed. When the third memory cell passes the validation and the current of the bit line coupled to the third memory cell exceeds the preset range (that is, the compensation check fails), the word line of the third program operation is the fifth word line, and the third program operation is performed on a memory cell belonging to the memory string to which the third memory cell belongs among memory cells coupled to the fifth word line, where the fifth word line may be one of a plurality of core word lines, the fifth word line may be a next word line of the third word line according to a programming sequence, and the fifth word line is adjacent to the third word line. When the third memory cell fails to pass the validation, and the current of the bit line coupled to the third memory cell exceeds the preset range (e.g., the compensation check fails), the third program operation continues to be performed on the third memory cell, where a corresponding program voltage can be further applied to the third word line and a further validation is performed to continue performing the third program operation on the third memory cell.

In some implementations, in the third phase, the peripheral circuit 102 is configured to: finish the third phase in response to the current of the bit line coupled to the third memory cell being within the preset range.

As shown in FIG. 18, regardless of whether the third memory cell passes the validation, when the current of the bit line coupled to the third memory cell is within the preset range (that is, the compensation check passes), the third phase may be finished, so that the operation phase may be entered.

In an implementation of the present disclosure, in the weight data writing process, in addition to that the second program operation needs to be performed in the second phase to write the weight data into the memory cell coupled to core word line, the first phase and the third phase need to be performed to perform corresponding compensation on the current of the memory string, so that the difference between the on-state currents of the memory strings is reduced, and compensation result is correspondingly checked in the third phase, thus the difference between the on-state currents of the memory strings meets preset requirement.

In some implementations, the preset range includes 30 nA to 50 nA.

It should be noted that the preset range provided in the foregoing implementations is merely an example, and is not used to limit a range of the preset range in the implementations of the present disclosure, and the preset range in the implementations of the present disclosure may be correspondingly adjusted according to actual requirements.

In the implementations of the present disclosure, the third program operation and the compensation check operation are performed in the third phase, so as to further reduce on-state current (Ion) deviation caused by factors such as patterns and processes. In the compensation check operation, the current in the saturation region is checked, the page buffer inside the semiconductor device can be used, and the analog-to-digital conversion circuit can also be used to ensure higher accuracy.

In some implementations, each of memory cells coupled to the fourth word line is in the erase state at least in the third phase.

In some implementations, the memory cells coupled to the fourth word line are always in the erase state in the first phase, the second phase, the third phase, and a subsequent operation phase.

In some implementations, in the third phase, the peripheral circuit 102 is configured to: pre-charge sensing nodes coupled to bit lines individually coupled to a plurality of third memory cells to the target voltage; the plurality of third memory cells are coupled to the same top select line, and the plurality of third memory cells are individually coupled to different bit lines; and obtain currents of the bit lines individually coupled to the plurality of third memory cells.

In the above implementations, when the memory cells coupled to the fourth word line are all in the erase state, compensation check operations for memory strings coupled to different bit lines can be performed in parallel, so that compensation check time can be saved, and compensation check efficiency can be improved.

In some implementations, in the operation phase, the peripheral circuit 102 is configured to: after the third phase, apply the second read voltage to the second word line, apply a corresponding input voltage to the top select line or the bottom select line coupled to the second memory cell, and apply corresponding turn-on voltages to word lines other than the second word line respectively; pre-charge the sensing node coupled to the bit line coupled to the second memory cell to the target voltage; and obtain the current of the bit line coupled to the second memory cell to obtain the analog calculation information.

In an implementation of the present disclosure, the first phase, the second phase, and the third phase all precede the operation phase.

In an implementation of the present disclosure, after the first phase, the second phase, and the third phase, the operation phase is entered, and the second operation is performed by using the memory cell coupled to the core word line to obtain the analog calculation information.

In some implementations, the semiconductor device 100 includes a three-dimensional NAND type memory.

Here, example structures and other details of the semiconductor device are similar to those in the above semiconductor devices, and are not described here again for brevity.

Based on the above semiconductor devices, an implementation of the present disclosure provides a system, including: at least one semiconductor device, where the semiconductor device is the semiconductor device according to any one of the foregoing implementations; and a controller coupled to the at least one semiconductor device and configured to send input data to the semiconductor device and receive an operation result of the semiconductor device.

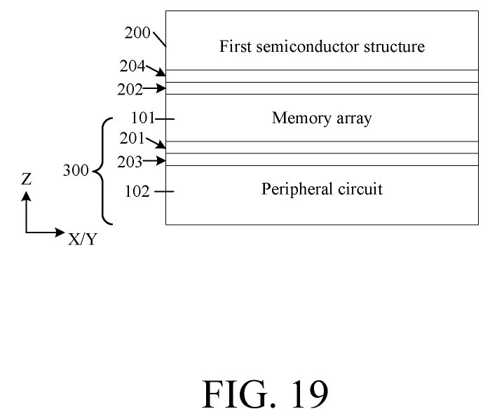

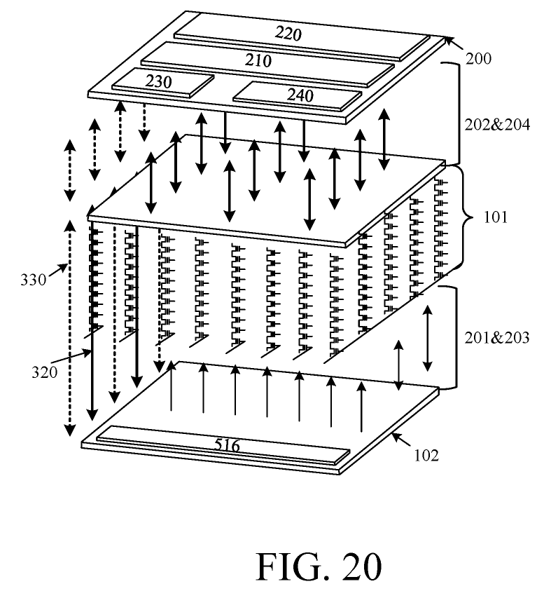

As shown in FIGS. 19 and 20, a system in an implementation of the present disclosure includes a first semiconductor structure 200 including a controller 240 and a second semiconductor structure 300 including the semiconductor device described above, where the semiconductor device includes a memory array 101 and a peripheral circuit 102. The first semiconductor structure 200 and the second semiconductor structure 300 are stacked along the Z-axis direction, and the memory array 101 and the peripheral circuit 102 are stacked along the Z-axis direction.

In some implementations, the first semiconductor structure 200 and the second semiconductor structure 300 may be connected in a bonding manner; and the memory array 101 and the peripheral circuit 102 may be connected in a bonding manner. The bonding connection includes a hybrid bonding connection (also referred to as a “metal/dielectric hybrid bonding connection”), which is a direct bonding technique, for example, bonding is formed between surfaces without using an intermediate layer such as solder or adhesive, and metal-metal bonding and dielectric-dielectric bonding can be achieved simultaneously. It should be noted that, the “bonding” referred to in the present disclosure may be any suitable bonding technology, such as hybrid bonding mentioned above, anodic bonding, fusion bonding, transfer bonding, adhesive bonding and eutectic bonding.

As shown in FIGS. 19 and 20, the second semiconductor structure 300 includes a first bonding layer 201 and a third bonding layer 203, and the system further includes a fourth bonding layer 204 and a second bonding layer 202. The first bonding layer 201 and the third bonding layer 203 are located between the memory array 101 and the peripheral circuit 102, and the memory array 101 is bonded to the peripheral circuit 102 through the first bonding layer 201 and the third bonding layer 203. The second bonding layer 202 and the fourth bonding layer 204 are located between the first semiconductor structure 200 and the memory array 101, and the second semiconductor structure 300 is bonded to the first semiconductor structure 200 through the second bonding layer 202 and the fourth bonding layer 204.

In some implementations, the semiconductor device may further include a first bonding interface between the third bonding layer 203 and the first bonding layer 201, and the system further includes a second bonding interface between the fourth bonding layer 204 and the second bonding layer 202. Data transfer between the memory array and the peripheral circuit may be achieved through interconnects (e.g., bonding contacts) across the first bonding interface. Data transfer between the first semiconductor structure and the second semiconductor structure may be achieved through interconnects (e.g., bonding contacts) across the second bonding interface.

In some implementations, a first interconnection layer (not shown) may be further included between the memory array 101 and the first bonding layer 201, and a second interconnection layer (not shown) may be further included between the peripheral circuit 102 and the third bonding layer 203. The first and second interconnect layers may include a plurality of interconnect structures, such as lateral lines and vias, where the interconnect structures may be formed in one or more interlayer dielectric (ILD) layers. The interconnect structures may include a conductive material including, but not limited to, W, Co, Cu, Al, silicide, or any combination thereof. The ILD layer in the interconnect layer may include a dielectric material including, but not limited to, silicon oxide, silicon nitride, silicon oxynitride, low-k dielectric, or any combination thereof.

In some implementations, the system further includes an analog-to-digital conversion circuit and a data processing circuit; the analog-to-digital conversion circuit is configured to convert the analog calculation information into digital calculation information; and the data processing circuit is configured to perform a first operation on the digital calculation information to obtain an operation result.

In some implementations, the system may include one or more computing-in-memory devices, and one or more other types of chips. For example, the chips include, but are not limited to, a sensor chip, a memory chip, a logic chip, etc. One or more computing-in-memory devices and one or more other types of chips may be integrated in a package, such as a printed circuit board (PCB) package. As such, the system can be applied to different scenarios.

As shown in FIG. 20, the first semiconductor structure 200 includes an analog-to-digital conversion circuit 210 and a data processing circuit 220. The analog-to-digital conversion circuit 210 is connected to the memory array 101 through the fourth bonding layer 204 and the second bonding layer 202, receives the analog calculation information output after the memory array 101 performs the second operation via the fourth bonding layer 204 and the second bonding layer 202, converts the analog calculation information into the digital calculation information by the analog-to-digital conversion circuit 210, transmits the final digital calculation information to the data processing circuit 220, and then the data processing circuit 220 performs the first operation on the digital calculation information.

In some implementations, the data processing circuit 220 includes a processor, which may include a special-purpose processor including, but not limited to, a CPU, a GPU, a digital signal processor (DSP), a tensor processing unit (TPU), a visual processing unit (VPU), a neural processing unit (NPU), a collaborative processing unit (SPU), a physics processing unit (PPU), and an image signal processor (ISP). In some examples, the data processing circuit is an NPU. The NPU may perform operations such as arithmetic/logical calculations, rotation and shift operations, compensation operations, activation operations, and pooling operations.

In an implementation of the present disclosure, the first operation includes one or more of compensation, activation, shift, or pooling operations.

As shown in FIG. 20, the second semiconductor structure 300 further includes a first connection structure 320 extending through the memory array 101 and connected to the bit line and the second bonding layer 202; where the memory array 101 is connected to the analog-to-digital conversion circuit 210 through the bit line, the first connection structure 320, the second bonding layer 202 and the fourth bonding layer 204. In some examples, the first connection structure 320 is a through array contact (TAC). In some implementations, one end of the first connection structure 320 is connected to the bit line, and the other end thereof is connected to the second bonding layer 202. Thus, the bit line may be connected to the analog-to-digital conversion circuit 210 through the first connection structure 320, the second bonding layer 202, and the fourth bonding layer 204. Thus, the analog calculation information is transmitted to the analog-to-digital conversion circuit 210.

In an implementation of the present disclosure, as shown in FIG. 20, the first semiconductor structure 200 further includes a first interface circuit 230. The first interface circuit 230 is configured to receive and send data between the system and other external devices. For instance, the first interface circuit 230 is configured to output an operation result obtained after the data processing circuit 220 performs the first operation to an external device. The controller 240 may be configured to control operations of the first semiconductor structure 200 and the second semiconductor structure 300. That is, the controller 240 may act as a memory controller managing data storage and transmission in the second semiconductor structure 300 and an operation controller managing data operation and transmission in the first semiconductor structure 200. In some implementations, the controller 240 is further configured to control data transmission between the first semiconductor structure 200 and the second semiconductor structure 300. In some implementations, the controller 240 is further configured to receive input data transmitted by the external device and transmit the input data to the second semiconductor structure 300.

In some implementations, the controller 240 is coupled to the second semiconductor structure 300 and the external device (e.g., a host), and configured to control the second semiconductor structure 300. The controller 240 may manage data stored in the second semiconductor structure 300 and communicate with the external device.

In some implementations, the controller 240 may be further configured to manage various functions with respect to data stored or to be stored in the second semiconductor structure 300, where the functions include, but are not limited to, bad block management, garbage collection, logical-to-physical address conversion, wear leveling, etc. In some implementations, the controller 240 is further configured to process error correction code (ECC) with respect to data read from or written to the second semiconductor structure. In some implementations, the controller 240 may also perform any other suitable functions, for example, formatting the second semiconductor structure.

In some implementations, the first interface circuit 230 may be configured in the controller 240, and an interface protocol may be used for the first interface circuit between the controller 240 and the external device, so that the controller 240 may communicate with the external device through at least one of various interface protocols, such as a USB protocol, an MMC protocol, a peripheral component Interconnect (PCI) protocol, a PCI express (PCI-E) protocol, an advanced technology attachment (ATA) protocol, a serial ATA protocol, a parallel ATA protocol, a small computer small interface (SCSI) protocol, an enhanced small disk interface (ESDI) protocol, an integrated drive electronics (IDE) protocol, a Firewire protocol, etc. Here, the first interface circuit 230 may also be referred to as a front-end interface. In some implementations, the controller 240 performs command/data interaction with the second semiconductor structure 300 through a plurality of configured channels. These channels are also referred to as back-end interfaces.

In an implementation of the present disclosure, the second semiconductor structure 300 further includes a fourth connection structure 330 extending through the memory array 101; one end of the fourth connection structure 330 is connected to the peripheral circuit 102, and the other end thereof is connected to the first interface circuit 230 through the fourth bonding layer 204 and the second bonding layer 202. Thus, the peripheral circuit 102 in the second semiconductor structure may be connected to the first interface circuit 230 through the fourth connection structure 330, and perform data transmission with other external devices through the first interface circuit 230.

It should be noted that dotted arrows in FIG. 20 are the fourth connection structure 330, and the number of the dotted arrows is merely an example, and is not intended to limit the present disclosure. It should be further noted that an interconnection structure coupled to the fourth connection structure 330 is further included in the bonding layers (the second bonding layer 202 and the fourth bonding layer 204) between the first semiconductor structure 200 and the memory array 101, so that the fourth connection structure 330 may be connected to the first interface circuit 230 through the second bonding layer 202 and the fourth bonding layer 204.

In an implementation of the present disclosure, in conjunction with FIGS. 6 and 20, the peripheral circuit further includes a second interface circuit 516; and the second semiconductor structure 300 is further connected to the first semiconductor structure 200 through the second interface circuit 516. That is, the second interface circuit 516 here is an interface coupled to the back-end interface of the above controller, and the second interface circuit 516 may also be an interface through which the second semiconductor structure 300 communicates with the first semiconductor structure 200. The second interface circuit 516 may be coupled to the control logic 512 and act as a control buffer to buffer control commands received from the host (not shown) and relay the control commands to the control logic 512 and to buffer status information received from the control logic 512 and relay the status information to the host. The second interface circuit 516 may also be coupled to a column decoder/bit line driver 506 via a data bus 518 and act as a data I/O interface and data buffer to buffer and relay data to or from the memory array 301.

In an implementation of the present disclosure, the system may be implemented as a multimedia card in the form of a universal flash memory device, a solid state drive (SSD), an MMC, an eMMC, an RS-MMC, and a micro MMC, a secure digital card in the form of an SD, a mini SD, and a micro SD, a personal computer memory card international association (PCMCIA) card type memory device, a peripheral component interconnect (PCI) type memory device, a PCI express (PCI-E) type memory device, a compact flash memory (CF) card, a smart media card, or a memory stick, etc. Particularly, the above system may be used in terminal products such as a computer, a television, a set-top box, and a vehicle. Here, for other example structures of the above system, reference is made to the implementations on the side of the above semiconductor device, since the present system adopts all the technical solutions of all the above implementations, at least all the beneficial effects brought by the technical solutions of the above implementations are achieved, which will not be repeated here.

Based on the above semiconductor devices, an implementation of the present disclosure provides an electronic device, including the system according to any one of the above implementations and a host coupled to the system.

In some implementations, the host may be a processor of the electronic device, such as a central processing unit (CPU) or a system on chip (SoC), where the SoC may be, for example, an application processor (AP).

In some implementations, the above electronic devices may be a mobile phone, a desktop computer, a tablet, a notebook, a server, an in-vehicle device, a wearable device, a mobile power supply, an intelligent sensor, a virtual reality (VR) device, an augmented reality (AR) device, or any other suitable electronic device having a computing-in-memory apparatus therein.

Based on the above semiconductor devices, an implementation of the present disclosure further provides a package structure, including: a package substrate, the semiconductor device according to any one of the above implementations, and a plastic packaging layer; the semiconductor device is disposed on the package substrate; and the plastic packaging layer encapsulates the semiconductor device.

In some implementations, the package substrate includes a substrate and an interposer formed on the substrate, a connection circuit is formed in the interposer, and the semiconductor device is disposed on a side of the interposer away from the substrate.

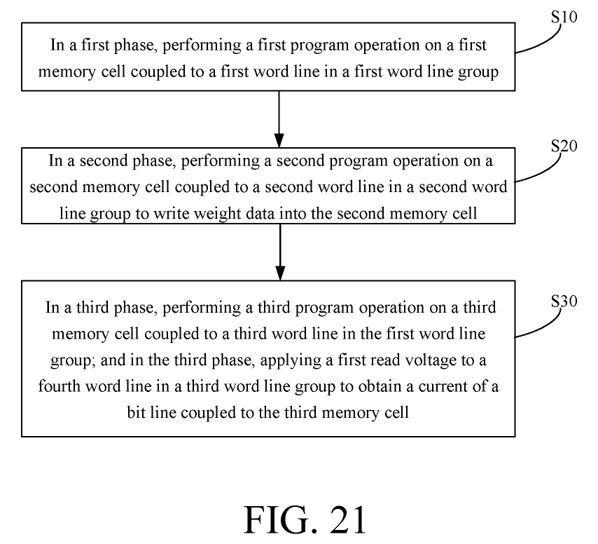

Based on a concept similar to the above semiconductor devices, the present disclosure further provides an operation method of a semiconductor device, FIG. 21 is a schematic flowchart of an operation method of a semiconductor device provided by an implementation of the present disclosure. As shown in FIG. 21, the operation method of the semiconductor device may include operations S10, S20, and S30.

At operation S10, in a first phase, the method may include performing a first program operation on a first memory cell coupled to a first word line in a first word line group; at operation S20, in a second phase, the method may include performing a second program operation on a second memory cell coupled to a second word line in a second word line group to write weight data into the second memory cell; at operation S30, in a third phase, the method may include performing a third program operation on a third memory cell coupled to a third word line in the first word line group; and in the third phase, applying a first read voltage to a fourth word line in a third word line group to obtain a current of a bit line coupled to the third memory cell.

It should be understood that the operations shown in FIG. 21 are not exclusive, and other operations may be performed before, after, or between any operations in the illustrated operations; the operations shown in FIG. 21 may be sequentially adjusted according to actual requirements.

In some implementations, memory cells in a memory array are configured to have an erase state; the memory cells in the erase state correspond to a first voltage-current relationship; a first current is a current in a saturation region in the first voltage-current relationship; and a first read voltage is a voltage corresponding to the first current in the first voltage-current relationship.

In some implementations, the memory cells in the memory array are configured to have a program state, and the memory cells in the program state correspond to a second voltage-current relationship; and the first read voltage is less than a voltage in a linear region in the second voltage-current relationship.

In some implementations, performing the first program operation on the first memory cell coupled to the first word line includes: applying a first validation voltage to the first word line in a validation phase of the first program operation; performing the second program operation on the second memory cell coupled to the second word line includes: applying a second validation voltage to the second word line in a validation phase of the second program operation; performing the third program operation on the third memory cell coupled to the third word line includes: applying a third validation voltage to the third word line in a validation phase of the third program operation; a threshold voltage of the first memory cell is a first threshold voltage after performing the first program operation on the first memory cell, and a threshold voltage of the third memory cell is a second threshold voltage after performing the third program operation on the third memory cell; the first validation voltage is different from the third validation voltage; or the first threshold voltage is different from the second threshold voltage.

In some implementations, the first threshold voltage is different from the second threshold voltage, and the first validation voltage is equal to the third validation voltage.

In some implementations, the first validation voltage is different from the third validation voltage, and the first threshold voltage is equal to the second threshold voltage.

In some implementations, the first validation voltage is greater than the third validation voltage.

In some implementations, the memory cells in the memory array are configured to have the erase state; the memory cells in the erase state correspond to first voltage-current relationship, and the memory cells in the program state correspond to the second voltage-current relationship; where a second current is a current in the linear region in the second voltage-current relationship, and a third current is a current in a transition region in the second voltage-current relationship; the first validation voltage is a voltage corresponding to the second current in the second voltage-current relationship; and the third validation voltage is a voltage corresponding to the third current in the second voltage-current relationship.

In some implementations, the first memory cell, the second memory cell, and the third memory cell belong to the same memory string.

In some implementations, performing the first program operation on the first memory cell coupled to the first word line includes: applying a corresponding program voltage to the first word line and applying a ground voltage to a bit line coupled to the first memory cell in a program phase of the first program operation; performing the second program operation on the second memory cell coupled to the second word line includes: applying a corresponding program voltage to the second word line and applying the ground voltage to a bit line coupled to the second memory cell in a program phase of the second program operation; and performing the third program operation on the third memory cell coupled to the third word line includes: applying a corresponding program voltage to the third word line and applying the ground voltage to a bit line coupled to the third memory cell in a program phase of the third program operation.

In some implementations, in the third phase, the operation method further includes: pre-charging a sensing node coupled to the bit line coupled to the third memory cell to a target voltage.

In some implementations, in the third phase, the operation method further includes: finishing the third phase in response to the current of the bit line coupled to the third memory cell being within a preset range.

In some implementations, the operation method further includes: performing the third program operation on a memory cell belonging to the third memory cell among memory cells coupled to a fifth word line in response to the third memory cell passing validation and the current of the bit line coupled to the third memory cell exceeding the preset range; or continuing to perform the third program operation on the third memory cell in response to the third memory cell failing the validation and the current of the bit line coupled to the third memory cell exceeding the preset range.

In some implementations, each of memory cells coupled to the fourth word line is in the erase state at least in the third phase.

In some implementations, in the third phase, the operation method further includes: pre-charging sensing nodes coupled to bit lines individually coupled to a plurality of third memory cells to a target voltage; the plurality of third memory cells are coupled to the same top select line, and the plurality of third memory cells are individually coupled to different bit lines; and obtaining the current of the bit line coupled to the third memory cell includes: obtaining currents of the bit lines individually coupled to the plurality of third memory cells.

In some implementations, the second phase follows the first phase, and the third phase follows the second phase.

In some implementations, the method further includes: performing an erase operation on each of the memory cells of the memory array before the first phase, the second phase, and the third phase.

In some implementations, in an operation phase, the operation method further includes: after the third phase, applying a second read voltage to the second word line, applying a corresponding input voltage to a top select line or a bottom select line coupled to the second memory cell, and applying corresponding turn-on voltages to word lines other than the second word line respectively; pre-charging a sensing node coupled to the bit line coupled to the second memory cell to a target voltage; and obtaining current of the bit line coupled to the second memory cell to obtain analog calculation information.

The relevant details of the operation method of the semiconductor device described above have been described in detail in the foregoing implementations on the side of the semiconductor device, and will not be repeated here for brevity.

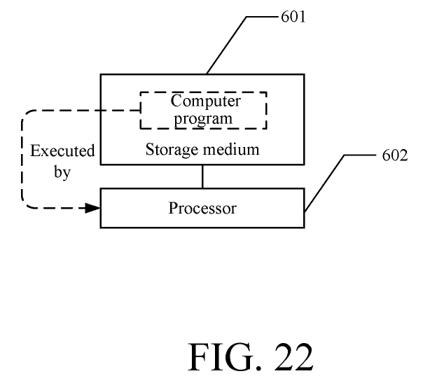

Based on a concept similar to the operation method of the semiconductor device described above, the present disclosure further provides a computer-readable storage medium, and FIG. 22 is a schematic structural diagram of a computer-readable storage medium provided by an implementation of the present disclosure. The computer-readable storage medium 601 stores computer programs thereon, and when the computer programs are executed by the processor 602, the operation method of the semiconductor device in any one of the foregoing implementations may be implemented.

In some implementations, the computer-readable storage medium 601 may be a memory such as a ferromagnetic random access memory (FRAM), a read-only memory (ROM), a programmable read-only memory (PROM), an erasable programmable read-only memory (EPROM), an electrically erasable programmable read-only memory (EEPROM), a flash memory, a magnetic surface memory, a compact disc, or a compact disc read-only memory (CD-ROM); or may be various devices including one or any combination of the above memory devices.

It should be understood that references to “some implementations” or “an implementation of the present disclosure” throughout the disclosure mean that particular features, structures, or characteristics related to the implementation are included in at least one implementation of the present disclosure. Therefore, “in some implementations” or “in an implementation of the present disclosure” appearing throughout the disclosure does not necessarily refer to the same implementation. In addition, the particular features, structures, or characteristics may be combined in one or more implementations in any suitable manner. It should be understood that in the various implementations of the present disclosure, the sequence numbers of the above processes do not imply the order of execution. The order of execution of each process should be determined by its function and internal logic, and should not impose any limitation on the implementation process of the implementations of the present disclosure. The above sequence numbers of the implementations of the present disclosure are merely for description and do not represent the superiority or inferiority of the implementations.

The above descriptions are merely preferred implementations of the present disclosure, and not intended to limit the patent scope of the present disclosure. Equivalent structure transformation made by utilizing the contents of the specification and the drawings of the present disclosure under the inventive concept of the present disclosure, or direct/indirect application to other related technical fields are both encompassed within the patent protection scope of the present disclosure.

What is claimed is:

1. A semiconductor device, comprising:
a memory array and a peripheral circuit coupled to the memory array, the memory array comprising a plurality of memory cells, the peripheral circuit configured to:
in a first phase, perform a first program operation on a first memory cell coupled to a first word line in a first word line group;
in a second phase, perform a second program operation on a second memory cell coupled to a second word line in a second word line group to write weight data into the second memory cell; and
in a third phase, perform a third program operation on a third memory cell coupled to a third word line in the first word line group; and in the third phase, apply a first read voltage to a fourth word line in a third word line group to obtain a current of a bit line coupled to the third memory cell.

2. The semiconductor device of claim 1, wherein the memory cells in the memory array are configured to have an erase state; the memory cells in the erase state correspond to a first voltage-current relationship; a first current is a current in a saturation region in the first voltage-current relationship; and the first read voltage is a voltage corresponding to the first current in the first voltage-current relationship.

3. The semiconductor device of claim 2, wherein the memory cells in the memory array are configured to have a program state, and the memory cells in the program state correspond to a second voltage-current relationship; and the first read voltage is less than a voltage in a linear region in the second voltage-current relationship.

4. The semiconductor device of claim 1, wherein the peripheral circuit is configured to:
apply a first validation voltage to the first word line in a validation phase of the first program operation;
apply a second validation voltage to the second word line in a validation phase of the second program operation; and
apply a third validation voltage to the third word line in a validation phase of the third program operation,
wherein a threshold voltage of the first memory cell is a first threshold voltage after the first program operation is performed on the first memory cell, and a threshold voltage of the third memory cell is a second threshold voltage after the third program operation is performed on the third memory cell, and
wherein the first validation voltage is different from the third validation voltage; or the first threshold voltage is different from the second threshold voltage.

5. The semiconductor device of claim 4, wherein the first threshold voltage is different from the second threshold voltage, and the first validation voltage is equal to the third validation voltage.

6. The semiconductor device of claim 4, wherein the first validation voltage is different from the third validation voltage, the first threshold voltage is equal to the second threshold voltage, and
the first validation voltage is greater than the third validation voltage.

7. The semiconductor device of claim 4, wherein memory cells in the memory array are configured to have an erase state; the memory cells in the erase state correspond to a first voltage-current relationship, and the memory cells in a program state correspond to a second voltage-current relationship; a second current is a current in a linear region in the second voltage-current relationship, and a third current is a current in a transition region in the second voltage-current relationship; the first validation voltage is a voltage corresponding to the second current in the second voltage-current relationship; and the third validation voltage is a voltage corresponding to the third current in the second voltage-current relationship.

8. The semiconductor device of claim 1, wherein the peripheral circuit is configured to:
apply a corresponding program voltage to the first word line and apply a ground voltage to a bit line coupled to the first memory cell in a program phase of the first program operation;
apply a corresponding program voltage to the second word line and apply the ground voltage to a bit line coupled to the second memory cell in a program phase of the second program operation; and
apply a corresponding program voltage to the third word line, and apply the ground voltage to a bit line coupled to the third memory cell in a program phase of the third program operation.

9. The semiconductor device of claim 1, wherein in the third phase, the peripheral circuit is configured to:
pre-charge a sensing node coupled to a bit line coupled to the third memory cell to a target voltage; and
finish the third phase on in response to a current of a bit line coupled to the third memory cell being within a preset range.

10. The semiconductor device of claim 4, wherein the peripheral circuit is configured to:
perform the third program operation on a memory cell belonging to a memory string to which the third memory cell belongs among memory cells coupled to a fifth word line on in response to the third memory cell passing a validation and a current of a bit line coupled to the third memory cell exceeding a preset range; or
continue to perform the third program operation on the third memory cell in response to the third memory cell failing a validation and a current of a bit line coupled to the third memory cell exceeding a preset range.

11. The semiconductor device of claim 9, wherein the preset range comprises 30 nA to 50 nA, and the first memory cell, the second memory cell, and the third memory cell belong to the same memory string.

12. The semiconductor device of claim 1, wherein the peripheral circuit is configured to:
apply the corresponding turn-on voltages to a top select line and a bottom select line coupled to the third memory cell, and word lines other than the fourth word line, respectively, during a same period of applying the first read voltage to the fourth word line.

13. The semiconductor device of claim 1, wherein each of memory cells coupled to the fourth word line is in an erase state at least in the third phase, and in the third phase, the peripheral circuit is configured to:
pre-charge each of sensing nodes coupled to bit lines individually coupled to a plurality of third memory cells to a target voltage; the plurality of third memory cells are coupled to the same top select line, and the plurality of third memory cells are individually coupled to different bit lines; and
obtain currents of the bit lines individually coupled to the plurality of third memory cells.

14. The semiconductor device of claim 1, wherein the peripheral circuit is configured to:
perform an erase operation on each of the memory cells of the memory array before the first phase, the second phase, and the third phase; and
wherein the second phase follows the first phase, and the third phase follows the second phase.

15. The semiconductor device of claim 1, wherein, in an operation phase, the peripheral circuit is configured to:
after the third phase, apply a second read voltage to the second word line, apply a corresponding input voltage to a top select line or a bottom select line coupled to the second memory cell, and apply a corresponding turn-on voltage to word lines other than the second word line;
pre-charge a sensing node coupled to a bit line coupled to the second memory cell to a target voltage; and
obtain a current of the bit line coupled to the second memory cell.

16. The semiconductor device of claim 1, wherein the semiconductor device comprises a three-dimensional NAND type memory.

17. A system, comprising:
at least one semiconductor device comprising a memory array and a peripheral circuit coupled to the memory array, the memory array comprising a plurality of memory cells, the peripheral circuit configured to:
in a first phase, perform a first program operation on a first memory cell coupled to a first word line in a first word line group;
in a second phase, perform a second program operation on a second memory cell coupled to a second word line in a second word line group to write weight data into the second memory cell; and
in a third phase, perform a third program operation on a third memory cell coupled to a third word line in the first word line group; and in the third phase, apply a first read voltage to a fourth word line in a third word line group to obtain a current of a bit line coupled to the third memory cell; and
a controller coupled to the at least one semiconductor device and configured to send input data to the semiconductor device and receive an operation result of the semiconductor device.

18. The system of claim 17, further comprising an analog-to-digital conversion circuit and a data processing circuit, wherein
the analog-to-digital conversion circuit is configured to convert analog calculation information into digital calculation information; and
the data processing circuit is configured to perform a first operation on the digital calculation information to obtain the operation result.

19. A method of operating a semiconductor device, comprising:
in a first phase, perform a first program operation on a first memory cell coupled to a first word line in a first word line group;
in a second phase, perform a second program operation on a second memory cell coupled to a second word line in a second word line group to write weight data into the second memory cell; and
in a third phase, perform a third program operation on a third memory cell coupled to a third word line in the first word line group; and in the third phase, perform a first read voltage to a fourth word line in a third word line group to obtain a current of a bit line coupled to the third memory cell.

20. The method of claim 19, wherein memory cells in a memory array are configured to have an erase state; the memory cells in the erase state correspond to a first voltage-current relationship; a first current is a current in a saturation region in the first voltage-current relationship; and the first read voltage is a voltage corresponding to the first current in the first voltage-current relationship; and
wherein the memory cells in the memory array are configured to have a program state, and the memory cells in the program state correspond to a second voltage-current relationship; and the first read voltage is less than a voltage in a linear region in the second voltage-current relationship.
